(19) United States
(12) Patent Application Publication
(10) Pub. No.: US 2024/0348216 A1
(43) Pub. Date: Oct. 17, 2024

(54) RADIO FREQUENCY MODULE

(71) Applicant: Murata Manufacturing Co., Ltd., Nagaokakyo-shi, Kyoto (JP)

(72) Inventors: Tomoya ODA, Nagaokakyo-shi (JP); Tetsurou ASHIDA, Nagaokakyo-shi (JP); Kouhei JITOUSHO, Nagaokakyo-shi (JP); Shohei IMAI, Nagaokakyo-shi (JP)

(73) Assignee: Murata Manufacturing Co., Ltd., Nagaokakyo-shi, Kyoto (JP)

(21) Appl. No.: 18/633,545

(22) Filed: Apr. 12, 2024

(30) Foreign Application Priority Data
Apr. 12, 2023 (JP) 2023-065149

(51) Int. Cl. H03F 3/24; H03F 1/02

(52) U.S. Cl. CPC H03F 3/245; H03F 1/0288; H03F 2200/451

(57) ABSTRACT

A radio frequency that includes a carrier amplifier and a peak amplifier, a 90° hybrid circuit connected to an input end of the carrier amplifier and an input end of the peak amplifier, a coupler connected to an output end of the carrier amplifier and an output end of the peak amplifier, and a control circuit configured to vary a threshold value of a bias voltage of the peak amplifier based on a radio frequency signal input to the 90° hybrid circuit or the carrier amplifier, and a signal indicating a drive level of the carrier amplifier, in which the carrier amplifier and the peak amplifier are included in an integrated circuit, the control circuit is included in an integrated circuit, and the integrated circuit and the integrated circuit are laminated.

### CROSS-REFERENCE TO RELATED APPLICATION

This application claims priority to Japanese Patent Application No. JP 2023-065149 filed on Apr. 12, 2023. The entire contents of the above-identified applications, including the specifications, drawings and claims, are incorporated herein by reference in their entirety.

### BACKGROUND OF THE DISCLOSURE

### 1. Field of the Disclosure

The present disclosure relates to a radio frequency module.

### 2. Description of the Related Art

As a highly efficient power amplifier circuit, a Doherty amplifier circuit is known. The Doherty amplifier circuit is generally configured such that a carrier amplifier that operates regardless of a power level of an input signal and a peak amplifier that is turned off assuming a power level of a radio frequency input signal is low and is turned on assuming the power level is high are connected in parallel. In the above-described configuration, in a case where the power level of the radio frequency input signal is high, the carrier amplifier operates while maintaining saturation at a saturation output power level. As a result, the Doherty amplifier circuit can improve the efficiency as compared with a normal power amplifier circuit.

In the technique described in U.S. Patent Application Publication No. 2016/0241209, saturation of a carrier amplifier is detected through a bias circuit of the carrier amplifier, and a bias circuit of a peak amplifier is controlled in response to the detection signal. In the technique described in U.S. Patent Application Publication No. 2020/0028472, saturation of a carrier amplifier is detected by an output signal of the carrier amplifier, and a bias circuit of a peak amplifier is controlled in response to the detection signal. In the technique described in Japanese Unexamined Patent Application Publication No. 2019-41277, a bias circuit of a peak amplifier is controlled in response to a radio frequency input signal level input to a Doherty amplifier circuit or a radio frequency input signal level input to a carrier amplifier.

### SUMMARY OF THE DISCLOSURE

However, in the techniques described in U.S. Patent Application Publication No. 2016/0241209 and U.S. Patent Application Publication No. 2020/0028472, the bias circuit of the peak amplifier can be controlled in response to a load fluctuation, but a timing at which the peak amplifier is turned on and off in response to the bias signal may be shifted, and a quality of a radio frequency output signal of the Doherty amplifier circuit may deteriorate. In addition, in the technique described in Japanese Unexamined Patent Application Publication No. 2019-41277, it is difficult to control the bias circuit of the peak amplifier in response to the load fluctuation, and the quality of the radio frequency output signal output from the Doherty amplifier circuit may deteriorate.

The present disclosure has been made to solve the above problems, and it is an object of the present disclosure to provide a radio frequency module including a Doherty amplifier circuit in which a deterioration in a quality of a radio frequency output signal is suppressed.

An aspect of the present disclosure relates to a radio frequency module including: a carrier amplifier and a peak amplifier; a branching circuit connected to an input end of the carrier amplifier and an input end of the peak amplifier; a synthesis circuit connected to an output end of the carrier amplifier and an output end of the peak amplifier; and a control circuit configured to vary a threshold value of a bias voltage of the peak amplifier based on a radio frequency signal input to the branching circuit or the carrier amplifier, and a signal indicating a drive level of the carrier amplifier, in which the carrier amplifier and the peak amplifier are included in a first integrated circuit, the control circuit is included in a second integrated circuit, and the first integrated circuit and the second integrated circuit are laminated.

Another aspect of the present disclosure relates to a radio frequency module including: a carrier amplifier and a peak amplifier; a branching circuit connected to an input end of the carrier amplifier and an input end of the peak amplifier; a synthesis circuit connected to an output end of the carrier amplifier and an output end of the peak amplifier; and a control circuit configured to vary a threshold value of a bias voltage of the peak amplifier, in which a first input end of the control circuit is connected to the input end of the carrier amplifier, a second input end of the control circuit is connected to a bias circuit of the carrier amplifier, an output end of the control circuit is connected to a bias circuit of the peak amplifier, the carrier amplifier and the peak amplifier are included in a first integrated circuit, the control circuit is included in a second integrated circuit, and the first integrated circuit and the second integrated circuit are laminated.

Still another aspect of the present disclosure relates to a radio frequency module including: a carrier amplifier and a peak amplifier; a branching circuit connected to an input end of the carrier amplifier and an input end of the peak amplifier; a synthesis circuit connected to an output end of the carrier amplifier and an output end of the peak amplifier; and a control circuit, in which a first input end of the control circuit is connected to an input end of the branching circuit or the input end of the carrier amplifier, a second input end of the control circuit is connected to the output end of the carrier amplifier, an output end of the control circuit is connected to the peak amplifier, the carrier amplifier and the peak amplifier are included in a first integrated circuit, the control circuit is included in a second integrated circuit, and the first integrated circuit and the second integrated circuit are laminated.

According to the present disclosure, it is possible to provide the radio frequency module including the Doherty amplifier circuit in which the deterioration in the quality of the radio frequency output signal is suppressed.

### BRIEF DESCRIPTION OF THE DRAWINGS

FIG. 1 is a circuit configuration diagram of a radio frequency module according to an embodiment;

FIG. 2 is a schematic diagram showing an example of a relationship between a radio frequency input signal of the radio frequency module according to the embodiment and a control signal output by a peak bias control circuit;

FIG. 3 is a circuit configuration diagram of the peak bias control circuit, a drive level detection circuit, and a bias circuit according to the embodiment;

FIG. 4 is a circuit configuration diagram of a radio frequency module according to Modification Example 1 of the embodiment;

FIG. 5 is a circuit configuration diagram of a radio frequency module according to Modification Example 2 of the embodiment;

FIG. 6 is a circuit configuration diagram of a radio frequency module according to Modification Example 3 of the embodiment;

FIG. 7A is a plan view of a radio frequency module according to Example 1;

FIG. 7B is a plan view of the radio frequency module according to Example 1;

FIG. 7C is a cross-sectional view of the radio frequency module according to Example 1;

FIG. 8A is a plan view of a radio frequency module according to Example 2;

FIG. 8B is a plan view of the radio frequency module according to Example 2;

FIG. 8C is a cross-sectional view of the radio frequency module according to Example 2;

FIG. 9A is a plan view of a radio frequency module according to Example 3;

FIG. 9B is a plan view of the radio frequency module according to Example 3;

FIG. 9C is a cross-sectional view of the radio frequency module according to Example 3;

FIG. 10A is a plan view of a radio frequency module according to Example 4;

FIG. 10B is a plan view of the radio frequency module according to Example 4;

FIG. 10C is a cross-sectional view of the radio frequency module according to Example 4;

FIG. 11A is a plan view of a radio frequency module according to Example 5;

FIG. 11B is a cross-sectional view of the radio frequency module according to Example 5;

FIG. 12A is a plan view of a radio frequency module according to Example 6;

FIG. 12B is a cross-sectional view of the radio frequency module according to Example 6;

FIG. 13A is a plan view of a radio frequency module according to Example 7;

FIG. 13B is a cross-sectional view of the radio frequency module according to Example 7;

FIG. 14A is a plan view of a radio frequency module according to Example 8;

FIG. 14B is a cross-sectional view of the radio frequency module according to Example 8;

FIG. 15A is a plan view of a radio frequency module according to Example 9;

FIG. 15B is a cross-sectional view of the radio frequency module according to Example 9;

FIG. 16A is a plan view of a radio frequency module according to Example 10;

FIG. 16B is a cross-sectional view of the radio frequency module according to Example 10;

FIG. 17A is a plan view of a radio frequency module according to Example 11;

FIG. 17B is a cross-sectional view of the radio frequency module according to Example 11;

FIG. 18A is a plan view of a radio frequency module according to Example 12; and

FIG. 18B is a cross-sectional view of the radio frequency module according to Example 12.

### DESCRIPTION OF THE PREFERRED EMBODIMENTS

Hereinafter, an embodiment of the present disclosure will be described in detail with reference to the drawings. All the following embodiments describe comprehensive or specific examples. Numerical values, shapes, materials, constituent elements, disposition and connection form of constituent elements, and the like shown in the following embodiment are examples and are not intended to limit the gist of the present disclosure.

Each drawing is a schematic diagram in which appropriate emphasis, omission, or adjustment of a ratio is made for the purpose of showing the present disclosure, and is not necessarily strictly shown, and may be different from the actual shape, positional relationship, and ratio. In each drawing, substantially the same configurations are denoted by the same reference numerals, and the duplicate description may be omitted or simplified.

In each drawing, an x-axis and a y-axis are axes that are orthogonal to each other on a plane parallel to a main surface of a substrate. Specifically, in a case where the substrate has a rectangular shape in a plan view, the x-axis is parallel to a first edge of the substrate, and the y-axis is parallel to a second edge of the substrate orthogonal to the first edge. In addition, a z-axis is an axis perpendicular to the main surface of the substrate, and a positive direction thereof indicates an up direction, and a negative direction thereof indicates a down direction.

In the component disposition of the present disclosure, the expression “in a plan view of the substrate” means that an object is viewed in an orthogonal projection from the z-axis positive side to the xy plane. The expression “A overlaps with B in a plan view” means that at least a part of a region of A that is orthogonally projected onto the xy plane overlaps with at least a part of a region of B that is orthogonally projected onto the xy plane. The expression “A is disposed between B and C” means that at least one of a plurality of line segments connecting any point in B and any point in C passes through A.

In the component disposition of the present disclosure, the expression “the component is disposed on the substrate” means that the component is disposed on the main surface of the substrate and that the component is disposed in the substrate. The expression “the component is disposed on the main surface of the substrate” means that the component is disposed above the main surface without making contact with the main surface (for example, the component is laminated on another component disposed while making contact with the main surface), in addition to meaning that the component is disposed while making contact with the main surface of the substrate. The expression “the component is disposed on the main surface of the substrate” may mean that the component is disposed in a recess portion formed in the main surface. The expression “the component is disposed in the substrate” means that the entire component is disposed between both main surfaces of the substrate, but a part of the component is not covered with the substrate, and only a part of the component is disposed in the substrate, in addition to meaning that the component is encapsulated in the module substrate.

In the circuit configuration of the present disclosure, the expression “connected” means a case of being electrically connected through another circuit element, as well as a case of being directly connected by a connection terminal and/or a wiring conductor. The expression “connected between A and B” means that the constituent element is connected to both A and B between A and B.

In addition, in the present disclosure, the expression “the component (element) A is disposed in series in a path B” means that both a signal input end and a signal output end of the component (element) A are connected to a wiring, an electrode, or a terminal constituting the path B.

In addition, in the component disposition of the present disclosure, the expression “A is disposed adjacent to B” means that A and B are disposed in close proximity to each other, and specifically means that no other circuit component is present in a space in which A faces B. Stated another way, the expression “A is disposed adjacent to B” means that none of a plurality of line segments reaching B along a normal direction of a surface from any point on the surface of A facing B passes through the circuit component other than A and B. Here, the circuit component means a component including an active element and/or a passive element. That is, the circuit component includes an active component including a transistor, a diode, or the like, and a passive component including an inductor, a transformer, a capacitor, a resistor, or the like, and does not include an electromechanical component including a terminal, a connector, a wiring, or the like.

In the present disclosure, a “terminal” means an end point of a conductor in an element. In a case where an impedance of the conductor between the elements is sufficiently low, the terminal is interpreted as not only a single point but also any point on the conductor between the elements or the entire conductor.

Furthermore, terms such as “parallel” and “perpendicular”, representing a relationship between elements, a term such as “rectangular” representing the shape of the element, and a numerical value range mean not only their exact meaning but also a substantially equivalent range, for example, the inclusion of an error of about a few percent.

The expression “A and B are laminated” means that A and B overlap with each other in a plan view. A and B may be in contact with each other, or another member may be interposed between A and B.

In addition, in the present specification, ordinal numbers such as “first” and “second” do not mean the number or order of the constituent elements unless otherwise specified, and are used for the purpose of avoiding confusion and distinguishing between the same type of constituent elements.

### Embodiment

### 1 Circuit Configuration of Radio Frequency Module 1

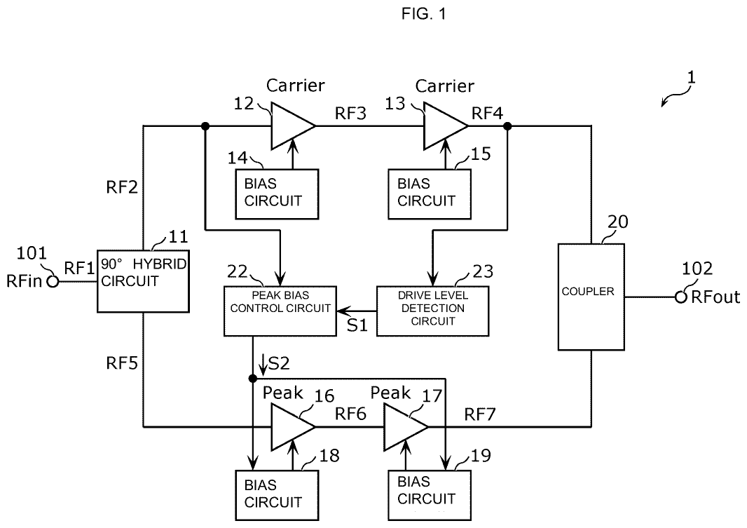

A circuit configuration of a radio frequency module 1 according to the present embodiment will be described with reference to FIG. 1. FIG. 1 is a circuit configuration diagram of the radio frequency module 1 according to the embodiment.

FIG. 1 shows an exemplary circuit configuration, and the radio frequency module 1 may be implemented using any of a variety of circuit implementations and circuit techniques. Therefore, the description of the radio frequency module 1 provided below should not be interpreted restrictively.

As shown in FIG. 1, the radio frequency module 1 includes carrier amplifiers 12 and 13, peak amplifiers 16 and 17, a 90° hybrid circuit 11, a coupler 20, a peak bias control circuit 22, a drive level detection circuit 23, bias circuits 14, 15, 18, and 19, a radio frequency input terminal 101, and a radio frequency output terminal 102. With the above-described configuration, the radio frequency module 1 constitutes a Doherty amplifier circuit.

The Doherty amplifier circuit means an amplifier circuit that realizes high efficiency by using a plurality of amplifier elements as a carrier amplifier and a peak amplifier. The carrier amplifier means an amplifier element that operates regardless of whether a power of a radio frequency input signal is low or high in the Doherty amplifier circuit. The peak amplifier means an amplifier element that mainly operates in a case where the power of the radio frequency input signal is high in the Doherty amplifier circuit. Therefore, in a case where the power of the radio frequency input signal is low, the radio frequency input signal is mainly amplified by the carrier amplifier, and in a case where the power of the radio frequency input signal is high, the radio frequency input signal is amplified and synthesized by the carrier amplifier and the peak amplifier. Due to such an operation, in the Doherty amplifier circuit, a load impedance viewed from the carrier amplifier increases at low output power, and the efficiency at low output power is improved.

The carrier amplifier 12 is an example of a first amplifier having an input end connected to a branching circuit. Specifically, the carrier amplifier 12 is a carrier amplifier disposed in a first stage (drive stage), and amplifies the radio frequency input signal input to the carrier amplifier 12. The carrier amplifier 13 is an example of a second amplifier having an input end connected to an output end of a first amplifier, and an output end connected to a synthesis circuit. Specifically, the carrier amplifier 13 is a carrier amplifier disposed in a final stage (power stage), and amplifies the radio frequency input signal input to the carrier amplifier 13.

The carrier amplifiers 12 and 13 are A-class (or AB-class) amplifier circuits that can perform an amplification operation on all power levels of the radio frequency input signals, and particularly, can perform a highly efficient amplification operation in a low output region and a medium output region.

The peak amplifier 16 is an example of a third amplifier having an input end connected to a branching circuit. Specifically, the peak amplifier 16 is a peak amplifier disposed in a first stage (drive stage), and amplifies the radio frequency input signal input to the peak amplifier 16. The peak amplifier 17 is an example of a fourth amplifier having an input end connected to an output end of the third amplifier, and an output end connected to a synthesis circuit. Specifically, the peak amplifier 17 is a peak amplifier disposed in a final stage (power stage), and amplifies the radio frequency input signal input to the peak amplifier 17.

The peak amplifiers 16 and 17 are C-class amplifier circuits that can perform an amplification operation in a region in which the power level of the radio frequency input signal is high. In the present embodiment, the peak amplifiers 16 and 17 are not supplied with a bias voltage (enter in an off state) in a region in which the power level of the radio frequency input signal is low, and are supplied with the bias voltage (enter in an on state) in a region in which the power level of the radio frequency input signal is high. The timing of turning on and off the bias voltage to the peak amplifiers 16 and 17 is controlled by a control signal S2 output from the peak bias control circuit 22.

Amplifier transistors included in the peak amplifiers 16 and 17 may be applied with a bias voltage smaller than a bias current applied to amplifier transistors included in the carrier amplifiers 12 and 13. Therefore, as the power level of the signal input to the peak amplifiers 16 and 17 is higher, the output impedance is lower. As a result, the peak amplifiers 16 and 17 can perform an amplification operation with low distortion in the high output region.

The number of stages of the Doherty amplifier circuit is set to two in the above description, but the present disclosure is not limited thereto. The number of stages of the Doherty amplifier circuit may be one or may be three or more.

The 90° hybrid circuit 11 is an example of the branching circuit, and is connected to the input end of the carrier amplifier 12 and the input end of the peak amplifier 16. The 90° hybrid circuit 11 divides a radio frequency signal RF1 into radio frequency signals RF2 and RF5 having phases different from each other by approximately 90°, outputs the radio frequency signal RF2 to the carrier amplifier 12, and outputs the radio frequency signal RF5 to the peak amplifier 16. The “approximately 90°” includes a phase of 90°+45°, in addition to a phase of 90°.

A preamplifier may be disposed on the input side of the 90° hybrid circuit 11.

The phase of the radio frequency signal RF5 is, for example, delayed by 90° from the radio frequency signal RF2. In addition, for example, the power of the radio frequency signal RF2 is equal to the power of the radio frequency signal RF5.

The bias circuit 14 supplies the bias voltage (and the bias current) to the carrier amplifier 12. The bias circuit 15 supplies the bias voltage (and the bias current) to the carrier amplifier 13. The carrier amplifier 12 amplifies the radio frequency signal RF2 and outputs an amplified radio frequency signal RF3 to the carrier amplifier 13. The carrier amplifier 13 amplifies the radio frequency signal RF3 and outputs an amplified radio frequency signal RF4 to the coupler 20.

The bias circuit 18 supplies the bias voltage (and the bias current) to the peak amplifier 16 based on the control signal S2 output from the peak bias control circuit 22. The bias circuit 19 supplies the bias voltage (and the bias current) to the peak amplifier 17 based on the control signal S2 output from the peak bias control circuit 22. The peak amplifier 16 amplifies the radio frequency signal RF5 and outputs an amplified radio frequency signal RF6 to the peak amplifier 17. The peak amplifier 17 amplifies the radio frequency signal RF6 and outputs an amplified radio frequency signal RF7 to the coupler 20.

The coupler 20 is an example of a synthesis circuit, and is connected to an output end of the carrier amplifier 13 and an output end of the peak amplifier 17 to synthesize the radio frequency signal RF4 and the radio frequency signal RF7. In a case where the radio frequency signal RF4 and the radio frequency signal RF7 are current-synthesized, the coupler 20 has, for example, a phase shifter connected between the carrier amplifier 13 and the radio frequency output terminal 102. The phase shifter delays the radio frequency signal RF4 of the carrier amplifier 13 by 90°. In addition, in a case where the radio frequency signal RF4 and the radio frequency signal RF7 are voltage-synthesized, the coupler 20 has, for example, a phase shifter connected between the peak amplifier 17 and the radio frequency output terminal 102, and a transformer connected to the phase shifter and the output end of the carrier amplifier 13. The phase shifter delays the radio frequency signal RF7 of the peak amplifier 17 by 90°. In the transformer, for example, both ends of a primary side coil are connected to the output ends of the phase shifter and the carrier amplifier 13, respectively, and both ends of a secondary side coil are connected to the radio frequency output terminal 102 and the ground, respectively.

The drive level detection circuit 23 is connected to the output end of the carrier amplifier 13, and is configured to output a signal S1 indicating a drive level of the carrier amplifier 13 to the peak bias control circuit 22, based on the radio frequency signal RF4 output by the carrier amplifier 13. Accordingly, the drive level detection circuit 23 detects, for example, an instantaneous minimum value of a voltage amplitude (or a current amplitude) of the radio frequency signal RF4. It is determined that the power (amplitude) of the radio frequency signal RF4 is larger as the instantaneous minimum value is smaller.

The drive level detection circuit 23 may be connected to the bias circuit 15 instead of the output end of the carrier amplifier 13, and may be configured to output the signal S1 indicating the drive level of the carrier amplifier 13 to the peak bias control circuit 22.

The signal S1 may be a signal (inversion signal) that is changed in a manner complementary to the drive level of the carrier amplifier 13.

The peak bias control circuit 22 is included in the control circuit, is connected to the input end of the carrier amplifier 12 and the drive level detection circuit 23, and is configured to output the control signal S2 for varying threshold values of the bias voltages of the peak amplifiers 16 and 17 to the bias circuits 18 and 19, based on the radio frequency signal RF2 input to the carrier amplifier 12 and the signal S1 indicating the drive level of the carrier amplifier 13. The threshold value of the bias voltage is a power value of the radio frequency input signal RFin to the radio frequency module 1 assuming the peak amplifiers 16 and 17 start the amplification operation, and is, for example, a power value of the radio frequency input signal RFin assuming the supply of the bias voltage to the peak amplifiers 16 and 17 is started (the bias voltage is raised).

The peak bias control circuit 22 may be connected to the input end of the 90° hybrid circuit 11 instead of an input end of the carrier amplifier 12. In this case, the peak bias control circuit 22 is configured to output the control signal S2 for varying the threshold values of the bias voltages of the peak amplifiers 16 and 17 to the bias circuits 18 and 19, based on the radio frequency signal RF1 and the signal S1.

The control signal S2 may be supplied only to the bias circuit 18 among the bias circuits 18 and 19.

### 2 Bias Control of Peak Bias Control Circuit 22

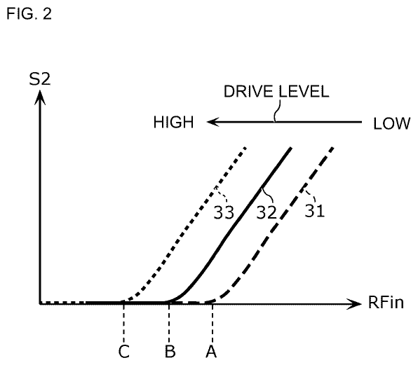

FIG. 2 is a schematic diagram showing an example of a relationship between the radio frequency input signal RFin of the radio frequency module 1 according to the embodiment and the control signal S2 output from the peak bias control circuit 22. In the same drawing, a horizontal axis represents the power of the radio frequency input signal RFin, and a vertical axis represents the intensity (voltage) of the control signal S2 output by the peak bias control circuit 22.

The peak bias control circuit 22 varies a rising point of the control signal S2 in response to the signal S1. A waveform 31 shows a relationship between the power of the radio frequency input signal RFin and the intensity of the control signal S2 in a case where the drive level of the carrier amplifier 13 is relatively low (instantaneous minimum value is relatively large). A waveform 32 shows a relationship between the power of the radio frequency input signal RFin and the intensity of the control signal S2 in a case where the drive level of the carrier amplifier 13 is relatively intermediate (instantaneous minimum value is relatively intermediate). A waveform 33 shows a relationship between the power of the radio frequency input signal RFin and the intensity of the control signal S2 in a case where the drive level of the carrier amplifier 13 is relatively high (instantaneous minimum value is relatively small).

In the present embodiment, in a case where the intensity (voltage) of the control signal S2 is relatively low, the bias voltage output from the bias circuits 18 and 19 is relatively low, and in a case where the intensity (voltage) of the control signal S2 is relatively high, the bias voltage output from the bias circuits 18 and 19 is relatively high.

In a case where the drive level of the carrier amplifier 13 is relatively low (instantaneous minimum value is relatively large), the peak bias control circuit 22 raises the control signal S2 assuming the power of the radio frequency input signal RFin reaches a threshold value A, as shown in the waveform 31. In response to this, the bias circuits 18 and 19 make the bias voltage higher as the power of the radio frequency input signal RFin is larger in a range in which the power of the radio frequency input signal RFin is equal to or larger than the threshold value A, for example.

In addition, in a case where the drive level of the carrier amplifier 13 is relatively intermediate (instantaneous minimum value is relatively intermediate), the peak bias control circuit 22 raises the control signal S2 assuming the power of the radio frequency input signal RFin reaches a threshold value B (B<A), as shown in the waveform 32. In response to this, the bias circuits 18 and 19 make the bias voltage higher as the power of the radio frequency input signal RFin is larger in a range in which the power of the radio frequency input signal RFin is equal to or larger than the threshold value B, for example.

In addition, in a case where the drive level of the carrier amplifier 13 is relatively high (instantaneous minimum value is relatively small), the peak bias control circuit 22 raises the control signal S2 assuming the power of the radio frequency input signal RFin reaches a threshold value C (C<B) as shown in the waveform 33. In response to this, the bias circuits 18 and 19 make the bias voltage higher as the power of the radio frequency input signal RFin is larger in a range in which the radio frequency input signal RFin is equal to or larger than the threshold value C, for example.

That is, the peak bias control circuit 22 is configured to vary the threshold value of the bias voltage of the peak amplifier 16 and/or the peak amplifier 17 based on the radio frequency input signal RFin and the signal indicating the drive level of the carrier amplifier 13.

For example, in a case where the radio frequency input signal RFin having large power is input, the peak bias control circuit 22 outputs the control signal S2 to the bias circuits 18 and 19 to cause the bias circuits 18 and 19 to output a predetermined bias voltage, thereby activating the peak amplifiers 16 and 17. As a result, it is possible to suppress the saturation of the carrier amplifiers 12 and 13.

The peak bias control circuit 22 according to the present embodiment detects the radio frequency input signal RFin to perform feedforward control of the bias voltage, and thus the peak bias control circuit 22 can respond much faster than the configuration in the related art in which the saturation of the carrier amplifier is detected. Therefore, even in a case where the power of the radio frequency input signal RFin is increased in a short time, the peak bias control circuit 22 can immediately respond to supply the bias voltage from the bias circuits 18 and 19 to quickly activate the peak amplifiers 16 and 17, and can suppress the momentary saturation of the carrier amplifiers 12 and 13.

It should be noted that, in a case where the temperature and other peripheral environments are changed (for example, a case where the load impedance fluctuates, a case where the gains of the carrier amplifiers 12 and 13 are increased at an extremely low temperature, or the like), the carrier amplifiers 12 and 13 may be saturated even assuming the power of the radio frequency input signal RFin is small.

On the other hand, in order to be capable of handling the above-described case, the peak bias control circuit 22 according to the present embodiment detects the signal S1 indicating the drive level of the carrier amplifiers 12 and 13 to perform feedback control of the bias voltage. Therefore, in a case where the carrier amplifiers 12 and 13 are close to saturation, the peak amplifiers 16 and 17 can be activated even assuming the power of the radio frequency input signal RFin is small.

That is, the peak bias control circuit 22 is configured to vary the threshold values (A, B, and C) of the bias voltages of the peak amplifiers 16 and 17 based on the radio frequency input signal RFin (or the radio frequency signal RF2) and the signal S1.

Therefore, since the peak bias control circuit 22 according to the present embodiment detects the radio frequency input signal RFin, even assuming a time is required to detect the drive level of the carrier amplifiers 12 and 13, the peak amplifiers 16 and 17 can be activated by supplying the predetermined bias voltage from the bias circuits 18 and 19 without saturating the carrier amplifiers 12 and 13. As a result, in the radio frequency module 1 including the Doherty amplifier circuit, it is possible to suppress the deterioration in the quality of the radio frequency output signal.

### 3 Circuit Configuration Examples of Peak Bias Control Circuit, Drive Level Detection Circuit, and Bias Circuit

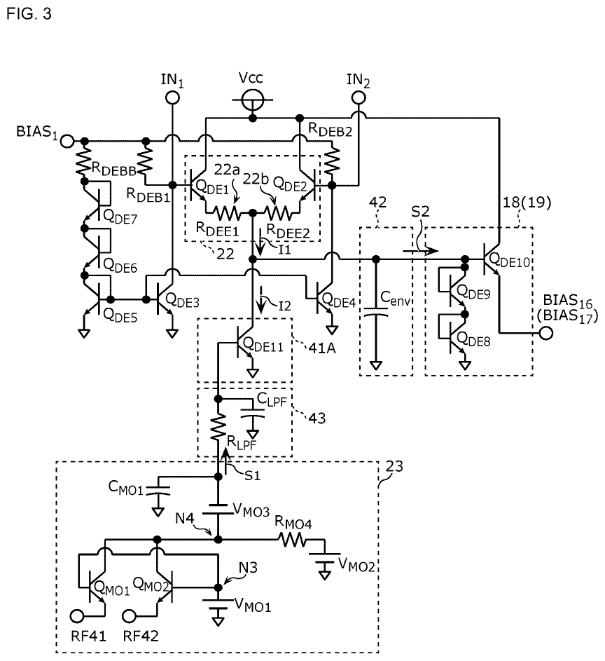

Next, circuit configurations of the peak bias control circuit 22, the drive level detection circuit 23, and the bias circuits 18 and 19 according to the present embodiment will be described. FIG. 3 is a circuit configuration diagram of the peak bias control circuit 22, the drive level detection circuit 23, and the bias circuits 18 and 19 according to the present embodiment. In the same drawing, in addition to the peak bias control circuit 22, the drive level detection circuit 23, the bias circuits 18 and 19, a constant current circuit 41A, and low pass filters 42 and 43 are shown. The constant current circuit 41A, and the low pass filters 42 and 43 need not be provided.

The peak bias control circuit 22 includes transistors Q_{DE1} and Q_{DE2}, and resistors R_{DEE1} and R_{DEE2}.

In the present disclosure, each transistor is a bipolar transistor, but each transistor is not limited thereto. As the bipolar transistor, a heterojunction bipolar transistor (HBT) is shown, but the present disclosure is not limited thereto. The transistor may be, for example, a field effect transistor (FET). The transistor may be a multi-finger transistor in which a plurality of unit transistors are electrically connected in parallel. The unit transistor refers to a minimum configuration for configuring the transistor.

A collector of the transistor Q_{DE1} is electrically connected to a power source (Vcc). An emitter of the transistor Q_{DE1} is electrically connected to one end of the resistor R_{DEE1}. The transistor Q_{DE1} and the resistor R_{DEE1} constitute an emitter follower circuit 22a.

The peak bias control circuit 22 may include a source follower circuit instead of the emitter follower circuit 22a.

A collector of the transistor Q_{DE2} is connected to the power source (Vcc). An emitter of the transistor Q_{DE2} is connected to one end of the resistor R_{DEE2}. The transistor Q_{DE2} and the resistor R_{DEE2} constitute an emitter follower circuit 22b.

The peak bias control circuit 22 may include a source follower circuit instead of the emitter follower circuit 22b.

The other end of the resistor R_{DEE1} and the other end of the resistor R_{DEE2} are connected to each other. The sum of an output current of the emitter follower circuit 22a and an output current of the emitter follower circuit 22b is an output current I1 of the peak bias control circuit 22.

Resistors R_{DEBB}, R_{DEB1}, and R_{DEB2}, and transistors Q_{DE5}, Q_{DE6}, and Q_{DE7} apply the bias voltage to bases of the transistors Q_{DE1} and Q_{DE2}.

One end of the resistor R_{DEBB}, one end of the resistor R_{DEB1}, and one end of the resistor R_{DEB2} are connected to each other.

The other end of the resistor R_{DEBB} is connected to a collector and a base of the transistor Q_{DE7}. That is, the transistor Q_{DE7} is diode-connected. An emitter of the transistor Q_{DE7} is connected to a collector and the base of the transistor Q_{DE6}. That is, the transistor Q_{DE6} is diode-connected. An emitter of the transistor Q_{DE6} is connected to a collector and a base of the transistor Q_{DE5}. That is, the transistor Q_{DE5} is diode-connected. An emitter of the transistor Q_{DE5} is connected to a reference potential. As the reference potential, a ground potential is shown, but the present disclosure is not limited thereto.

A bias current BIAS₁ is input to one end of the resistor R_{DEBB}, one end of the resistor R_{DEB1}, and one end of the resistor R_{DEB2}. The resistor R_{DEBB}, the transistor Q_{DE7}, the transistor Q_{DE6}, and the transistor Q_{DE5} generate a constant voltage. This voltage is input to a base of the transistor Q_{DE1} through the resistor R_{DEB1} and is input to a base of the transistor Q_{DE2} through the resistor R_{DEB2}.

Each of the transistors Q_{DE3} and Q_{DE4} is connected to the transistor Q_{DE5} by a current mirror. A collector of the transistor Q_{DE3} is connected to the base of the transistor Q_{DE1}. As a result, the transistor Q_{DE3} can adjust a base current of the transistor Q_{DE1}. A collector of the transistor Q_{DE4} is connected to the base of the transistor Q_{DE2}. As a result, the transistor Q_{DE4} can adjust a base current of the transistor Q_{DE2}.

In the present circuit configuration example, radio frequency signals IN₁ and IN₂ obtained by converting the radio frequency signal RF2 into differential signals are input to the base of the transistor Q_{DE1} and the base of the transistor Q_{DE2}. The radio frequency signals IN₁ and IN₂ can be obtained, for example, by inputting the radio frequency signal RF2 to a balun.

The other end of the resistor R_{DEE1} and the other end of the resistor R_{DEE2} are connected to the constant current circuit 41A. The constant current circuit 41A includes a transistor Q_{DE11}. The constant current circuit 41A is a current bias circuit of the peak bias control circuit 22.

The drive level detection circuit 23 includes a resistor R_{MO4}, constant voltage sources V_{MO1}, V_{MO2}, and V_{MO3}, transistors Q_{MO1} and Q_{MO2}, and a capacitor C_{MO1}.

In the present circuit configuration example, the carrier amplifier 13 (see FIG. 1) is a differential amplifier and outputs radio frequency signals RF41 and RF42 that constitute a pair of differential signals.

The radio frequency signal RF41 is input to an emitter of the transistor Q_{MO1}. The emitter of the transistor Q_{MO1} is connected to an output terminal (collector or drain of an output transistor) of one amplifier in the carrier amplifier 13.

The radio frequency signal RF42 is input to an emitter of the transistor Q_{MO2}. The emitter of the transistor Q_{MO2} is connected to an output terminal (collector or drain of an output transistor) of the other amplifier in the carrier amplifier 13.

A base of the transistor Q_{MO1} and a base of the transistor Q_{MO2} are connected to a node N3. A collector of the transistor Q_{MO1} and a collector of the transistor Q_{MO2} are connected to a node N4.

The constant voltage source V_{MO1} applies a voltage to the node N3. That is, the constant voltage source V_{MO1} supplies a bias to the base of the transistor Q_{MO1} and the base of the transistor Q_{MO2}.

The resistor R_{MO4} and the constant voltage source V_{MO2} apply a voltage to the node N4. That is, the resistor R_{MO4} and the constant voltage source V_{MO2} supply a bias to the collector of the transistor Q_{MO1} and the collector of the transistor Q_{MO2}.

One end of the constant voltage source V_{MO3} is connected to the node N4, and the other end of the constant voltage source V_{MO3} is connected to one end of the capacitor C_{MO1}. The other end of the capacitor C_{MO1} is connected to the reference potential.

The constant voltage source V_{MO3} outputs the signal S1 from the other end. The capacitor C_{MO1} shunts and smooths a radio frequency component of the signal S1.

Each of the constant voltage sources V_{MO1} and V_{MO2} need only be configured with the resistor and the transistor, and need only be configured to output a substantially constant voltage. The constant voltage source V_{MO3} need only be configured with a diode-connected transistor and need only generate an approximately constant voltage drop.

The constant current circuit 41A includes the transistor Q_{DE11}.

The low pass filter 43 includes a resistor R_{LPF} and a capacitor C_{LPF}. One end of the resistor R_{LPF} is connected to the other end of the constant voltage source V_{MO3}. The other end of the resistor R_{LPF} is connected to one end of the capacitor C_{LPF} and a base of the transistor Q_{DE11}. The other end of the capacitor C_{LPF} is connected to the reference potential. The low pass filter 43 allows the signal S1 to pass in a low range and outputs the signal to the base of the transistor Q_{DE11}.

The low pass filter 42 includes a capacitor Cₑₙᵥ. One end of the capacitor Cₑₙᵥ is electrically connected to the other end of the resistor R_{DEE1}, the other end of the resistor R_{DEE2}, and the collector of the transistor Q_{DE11}. The other end of the capacitor Cₑₙᵥ is connected to the reference potential.

The capacitor Cₑₙᵥ is charged or discharged by a difference between the output current I1 of the peak bias control circuit 22 and a collector current I2 of the transistor Q_{DE11}. The voltage of the capacitor Cₑₙᵥ is the control signal S2 (voltage). The capacitor Cₑₙᵥ terminates and removes a radio frequency component (for example, a carrier frequency signal component) of the control signal S2 at the reference potential and allows only the low frequency component to pass. As a result, the capacitor Cₑₙᵥ can be appropriately biased by the bias circuits 18 and 19 on a subsequent stage and a bias supply target transistor (amplifier transistor).

The bias circuit 18 includes transistors Q_{DE8}, Q_{DE9}, and Q_{DE10}. The circuit configuration of the bias circuit 19 (see FIG. 1) is the same as the circuit configuration of the bias circuit 18, and thus the description thereof will be omitted.

The transistor Q_{DE9} is diode-connected. A collector and a base of the transistor Q_{DE9} are electrically connected to one end of the capacitor Cₑₙᵥ. An emitter of the transistor Q_{DE9} is connected to a collector and a base of the transistor Q_{DE8}. The transistor Q_{DE5} is diode-connected. An emitter of the transistor Q_{DE8} is connected to the reference potential. A current corresponding to the voltage of the capacitor Cₑₙᵥ flows through the transistors Q_{DE9} and Q_{DE8}.

A collector of the transistor Q_{DE10} is connected to the power source (Vcc). A base of the transistor Q_{DE10} is connected to the collector and the base of the transistor Q_{DE9}. An emitter voltage of the transistor Q_{DE10} is output to the peak amplifier 16 (17) as the bias voltage BIAS₁₆ (BIAS₁₇).

Hereinafter, the operations of the drive level detection circuit 23 and the peak bias control circuit 22 will be described.

An output end voltage of the carrier amplifier 13 in the final stage vibrates about the bias voltage with the voltage amplitude of the radio frequency signal RF4. Assuming the carrier amplifiers 13 are saturated, a situation occurs in which the voltage amplitude of the radio frequency signal RF4 is increased to be substantially equal to the bias voltage. In this case, an instant in which the instantaneous minimum value of the radio frequency signal RF4 approaches 0 V occurs. This instant is an instant in which the amplification effect is not obtained, and is associated with the phenomenon of saturation of the amplifier. In the present circuit configuration example, the drive level of the carrier amplifier 13 is detected by using the saturation principle.

Specifically, within periods of the radio frequency signals RF41 and RF42, the transistors Q_{MO1} and Q_{MO2} are in an on state only in a period in which the voltages of the radio frequency signals RF41 and RF42 are lower than the voltage obtained by subtracting the voltage drop by the threshold voltage of the transistors Q_{MO1} and Q_{MO2} from the voltage of the constant voltage source V_{MO1}.

Assuming the carrier amplifier 13 operates with sufficient margin with respect to the saturation, there is no period in which the transistors Q_{MO1} and Q_{MO2} are in an on state, and thus no collector current flows. Therefore, no current flows through the resistor R_{MO4}, and thus no voltage drop is generated. Therefore, the signal S1 is a voltage obtained by subtracting the voltage of the constant voltage source V_{MO3} from the voltage of the constant voltage source V_{MO2}.

On the other hand, assuming the amplitudes of the radio frequency signals RF41 and RF42 are increased, the transistors Q_{MO1} and Q_{MO2} are in an on state for a certain period, and thus the collector current flows. Therefore, the current flows through the resistor R_{MO4}, and thus the voltage drop is generated.

Assuming the amplitudes of the radio frequency signals RF41 and RF42 are further increased, the period in which the transistors Q_{MO1} and Q_{MO2} are in an on state is lengthened, and thus a larger collector current flows. Therefore, a larger current flows through the resistor R_{MO4}, and thus a larger voltage drop is generated.

Therefore, the signal S1 is a voltage in which the radio frequency signals RF41 and RF42 are smaller by the voltage drop in the resistor R_{MO4} from the voltage at the time of the small signal as the drive level of the carrier amplifier 13 is higher. The signal S1 can be regarded as a signal (inversion signal) that is changed in a manner complementary to the drive level of the carrier amplifier 13.

On the other hand, in the peak bias control circuit 22, the transistor Q_{DE1} is in an on state assuming the radio frequency signal IN₁ is equal to or larger than the threshold voltage of the transistor Q_{DE1}, and outputs the emitter current. The transistor Q_{DE2} is in an on state assuming the radio frequency signal IN₂ is equal to or larger than the threshold voltage of the transistor Q_{DE2}, and outputs an emitter current. That is, as the amplitudes of the radio frequency signals IN₁ and IN₂ (radio frequency signals RF2) are larger, the output current of the peak bias control circuit 22 is larger. In addition, as the amplitudes of the radio frequency signals IN₁ and IN₂ (radio frequency signals RF2) are smaller, the output current of the peak bias control circuit 22 is smaller.

In addition, as described in the operation of the drive level detection circuit 23, the signal S1 is smaller as the drive level of the carrier amplifier 13 is higher, and is larger as the drive level of the carrier amplifier 13 is lower.

That is, as the drive level of the carrier amplifier 13 is relatively higher (closer to saturation), the collector current I2 of the transistor Q_{DE11} is smaller. In addition, as the drive level of the carrier amplifier 13 is relatively lower (amplification rate is lower), the collector current I2 of the transistor Q_{DE11} is larger.

In a case where the above description is comprehensively considered, the voltage of the capacitor Cₑₙᵥ is likely to be larger as the drive level of the carrier amplifier 13 is relatively higher (closer to saturation). The voltage of the capacitor Cₑₙᵥ is less likely to be larger as the drive level of the carrier amplifier 13 is relatively lower (the amplification rate is lower). The voltage of the capacitor Cₑₙᵥ is likely to be larger as the power of the radio frequency signal RF2 is larger. The voltage of the capacitor Cₑₙᵥ is less likely to be larger as the power of the radio frequency signal RF2 is smaller.

The peak bias control circuit 22 raises the control signal S2 assuming the power of the radio frequency input signal RFin reaches the threshold value C in a case where the drive level of the carrier amplifier 13 is relatively high (instantaneous minimum value is relatively small), and raises the control signal S2 assuming the power of the radio frequency input signal RFin reaches the threshold value A larger than the threshold value C in a case where the drive level of the carrier amplifier 13 is relatively low (instantaneous minimum value is relatively large).

### 4 Modification Example of Circuit Configuration of Radio Frequency Module

Hereinafter, a modification example of the circuit configuration of the radio frequency module will be described.

### 4.1 Modification Example 1

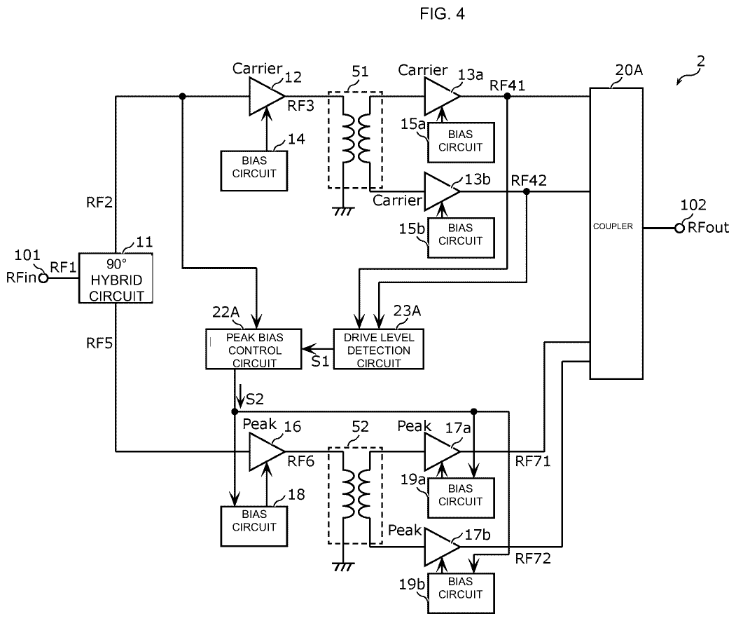

FIG. 4 is a circuit configuration diagram of a radio frequency module 2 according to Modification Example 1 of the embodiment. The radio frequency module 2 according to the present modification example includes carrier amplifiers 12, 13a, and 13b, peak amplifiers 16, 17a, and 17b, the 90° hybrid circuit 11, a coupler 20A, a peak bias control circuit 22A, a drive level detection circuit 23A, bias circuits 14, 15a, 15b, 18, 19a, and 19b, transformers 51 and 52, the radio frequency input terminal 101, and the radio frequency output terminal 102. With the above-described configuration, the radio frequency module 2 constitutes a Doherty amplifier circuit. The radio frequency module 2 according to the present modification example is different from the radio frequency module 1 according to the embodiment in that each of the carrier amplifier and the peak amplifier in the final stage (power stage) is a differential amplifier. Hereinafter, the radio frequency module 2 according to the present modification example will be described, and the same configuration as the configuration of the radio frequency module 1 according to the embodiment will not be described, and a different configuration will be mainly described.

The carrier amplifier 12 is an example of a first amplifier having an input end connected to a branching circuit. Specifically, the carrier amplifier 12 is a carrier amplifier disposed in a first stage (drive stage), and amplifies the radio frequency input signal input to the carrier amplifier 12. The carrier amplifiers 13a and 13b are each an example of a second amplifier having an input end connected to an output end of the first amplifier and an output end connected to a synthesis circuit. Specifically, the carrier amplifiers 13a and 13b are carrier amplifiers disposed in the final stage (power stage). The carrier amplifiers 13a and 13b are connected in parallel between the 90° hybrid circuit 11 and the coupler 20A to constitute a differential amplifier. Specifically, the carrier amplifiers 13a and 13b are connected in parallel between the carrier amplifier 12 and the coupler 20A.

The transformer 51 has a primary side coil and a secondary side coil, and converts an unbalanced signal input to one end of the primary side coil into a balanced signal, and outputs the balanced signal from both ends of the secondary side coil. Specifically, one end of the primary side coil is connected to the output end of the carrier amplifier 12, the other end of the primary side coil is connected to the reference potential, one end of the secondary side coil is connected to the input end of the carrier amplifier 13a, and the other end of the secondary side coil is connected to the input end of the carrier amplifier 13b.

The output end of the carrier amplifier 13a and the output end of the carrier amplifier 13b are connected to the coupler 20A.

The carrier amplifiers 12, 13a, and 13b are A-class (or AB-class) amplifier circuits that can perform an amplification operation on all power levels of the radio frequency input signals, and particularly, can perform a highly efficient amplification operation in a low output region and a medium output region.

The peak amplifier 16 is an example of a third amplifier having an input end connected to a branching circuit. Specifically, the peak amplifier 16 is a peak amplifier disposed in a first stage (drive stage), and amplifies the radio frequency input signal input to the peak amplifier 16. The peak amplifiers 17a and 17b are each an example of a fourth amplifier having an input end connected to an output end of a third amplifier and an output end connected to a synthesis circuit. Specifically, the peak amplifiers 17a and 17b are peak amplifiers disposed in the final stage (power stage). The peak amplifiers 17a and 17b are connected in parallel between the 90° hybrid circuit 11 and the coupler 20A to constitute a differential amplifier. Specifically, the peak amplifiers 17a and 17b are connected in parallel between the peak amplifier 16 and the coupler 20A.

The transformer 52 has a primary side coil and a secondary side coil, and converts an unbalanced signal input to one end of the primary side coil into a balanced signal, and outputs the balanced signal from both ends of the secondary side coil. Specifically, one end of the primary side coil is connected to the output end of the peak amplifier 16, the other end of the primary side coil is connected to the reference potential, one end of the secondary side coil is connected to the input end of the peak amplifier 17a, and the other end of the secondary side coil is connected to the input end of the peak amplifier 17b.

The output end of the peak amplifier 17a and the output end of the peak amplifier 17b are connected to the coupler 20A.

The peak amplifiers 16, 17a, and 17b are C-class amplifier circuits that can perform an amplification operation in a region in which the power level of the radio frequency input signal is high.

In the present modification example, the peak amplifiers 16, 17a, and 17b are not supplied with a bias voltage (enter in an off state) in a region in which the power level of the radio frequency input signal is low, and are supplied with the bias voltage (enter in an on state) in a region in which the power level of the radio frequency input signal is high. The timing of turning on and off the bias voltage to the peak amplifiers 16, 17a, and 17b is controlled by the control signal S2 output from the peak bias control circuit 22A.

The amplifier transistors included in the peak amplifiers 16, 17a, and 17b may be applied with the bias voltage smaller than the bias current applied to the amplifier transistors included in the carrier amplifiers 12, 13a, and 13b. Therefore, as the power levels of the signals input to the peak amplifiers 16, 17a, and 17b are higher, the output impedance is lower. As a result, the peak amplifiers 16, 17a, and 17b can perform an amplification operation with low distortion in the high output region.

The number of stages of the Doherty amplifier circuit is set to two in the above description, but the present disclosure is not limited thereto. The number of stages of the Doherty amplifier circuit may be one or may be three or more.

The bias circuit 14 supplies the bias voltage (and the bias current) to the carrier amplifier 12. The bias circuit 15a supplies the bias voltage (and the bias current) to the carrier amplifier 13a. The bias circuit 15b supplies the bias voltage (and the bias current) to the carrier amplifier 13b.

The carrier amplifier 12 amplifies the radio frequency signal RF2 and outputs the amplified radio frequency signal RF3 to the transformer 51. The transformer 51 converts the unbalanced radio frequency signal RF3 into the balanced radio frequency signal. The carrier amplifier 13a amplifies one of the balanced radio frequency signals and outputs the amplified radio frequency signal RF41 to the coupler 20A. The carrier amplifier 13b amplifies the other of the balanced radio frequency signals and outputs the amplified radio frequency signal RF42 to the coupler 20A.

The bias circuit 18 supplies the bias voltage (and the bias current) to the peak amplifier 16 based on the control signal S2 output from the peak bias control circuit 22A. The bias circuit 19a supplies the bias voltage (and the bias current) to the peak amplifier 17a based on the control signal S2 output from the peak bias control circuit 22A. The bias circuit 19b supplies the bias voltage (and the bias current) to the peak amplifier 17b based on the control signal S2 output from the peak bias control circuit 22A.

The peak amplifier 16 amplifies the radio frequency signal RF5 and outputs the amplified radio frequency signal RF6 to the transformer 52. The transformer 52 converts the unbalanced radio frequency signal RF6 into the balanced radio frequency signal. The peak amplifier 17a amplifies one of the balanced radio frequency signals and outputs an amplified radio frequency signal RF71 to the coupler 20A. The peak amplifier 17b amplifies the other of the balanced radio frequency signals and outputs an amplified radio frequency signal RF72 to the coupler 20A.

The coupler 20A is an example of a synthesis circuit, is connected to the output end of the carrier amplifier 13a, the output end of the carrier amplifier 13b, the output end of the peak amplifier 17a, and the output end of the peak amplifier 17b, and synthesizes the radio frequency signals RF41, RF42, RF71, and RF72.

The drive level detection circuit 23A is connected to the output ends of the carrier amplifiers 13a and 13b, and is configured to output the signal S1 indicating the drive level of the carrier amplifiers 13a and 13b to the peak bias control circuit 22A, based on the radio frequency signal RF41 output by the carrier amplifier 13a and the radio frequency signal RF42 output by the carrier amplifier 13b. Accordingly, the drive level detection circuit 23A detects, for example, the instantaneous minimum value of the voltage amplitude (or the current amplitude) of the radio frequency signals RF41 and RF42. As the instantaneous minimum value is smaller, the power (amplitude) of the radio frequency signals RF41 and RF42 is determined to be larger.

The drive level detection circuit 23A may be connected to the bias circuit 15a instead of the output end of the carrier amplifier 13a, may be connected to the bias circuit 15b instead of the output end of the carrier amplifier 13b, and may be configured to output the signal S1 indicating the drive level of the carrier amplifiers 13a and 13b to the peak bias control circuit 22A.

The signal S1 may be a signal (inversion signal) that is changed in a manner complementary to the drive levels of the carrier amplifiers 13a and 13b.

The peak bias control circuit 22A is included in the control circuit, is connected to the input end of the carrier amplifier 12 and the drive level detection circuit 23A, and is configured to output the control signal S2 for varying the threshold values of the bias voltages of the peak amplifiers 16, 17a, and 17b to the bias circuits 18, 19a, and 19b, based on the radio frequency signal RF2 input to the carrier amplifier 12 and the signal S1 indicating the drive level of the carrier amplifiers 13a and 13b.

The peak bias control circuit 22A may be connected to the input end of the 90° hybrid circuit 11 instead of an input end of the carrier amplifier 12. In this case, the peak bias control circuit 22A is configured to output the control signal S2 for varying the threshold values of the bias voltages of the peak amplifiers 16, 17a, and 17b to the bias circuits 18, 19a, and 19b, based on the radio frequency signal RF1 and the signal S1.

The control signal S2 may be supplied only to the bias circuit 18 among the bias circuits 18, 19a, and 19b.

The peak bias control circuit 22A varies the rising point of the control signal S2 in response to the signal S1, as in the graph showing the relationship between the radio frequency input signal RFin and the control signal S2 shown in FIG. 2. That is, the peak bias control circuit 22A is configured to vary the threshold values of the bias voltages of the peak amplifier 16, and the peak amplifiers 17a and 17b based on the radio frequency signal RF2 (or the radio frequency input signal RFin) and the signal S1 indicating the drive level of the carrier amplifiers 13a and 13b.

The peak bias control circuit 22A according to the present modification example is configured to vary the threshold values (A, B, and C) of the bias voltages of the peak amplifiers 16, 17a, and 17b based on the radio frequency signal RF2 (or the radio frequency input signal RFin) and the signal S1.

Therefore, since the peak bias control circuit 22A according to the present modification example detects the radio frequency signal RF2 (or the radio frequency input signal RFin), even assuming a time is required to detect the drive level of the carrier amplifiers 12, 13a, and 13b, the peak amplifiers 16, 17a, and 17b can be activated by supplying the predetermined bias voltage from the bias circuits 18, 19a, and 19b without saturating the carrier amplifiers 12, 13a, and 13b. As a result, in the radio frequency module 2 including the Doherty amplifier circuit, it is possible to suppress the deterioration in the quality of the radio frequency output signal.

### 4.2 Modification Example 2

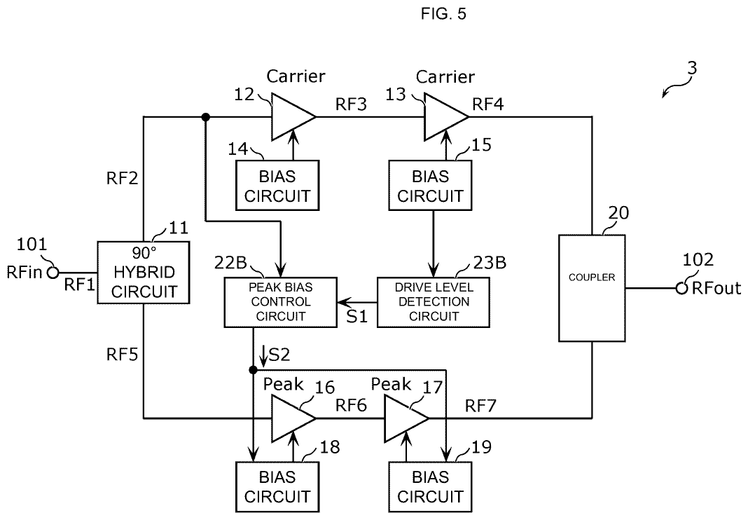

FIG. 5 is a circuit configuration diagram of a radio frequency module 3 according to Modification Example 2 of the embodiment. The radio frequency module 3 according to the present modification example includes the carrier amplifiers 12 and 13, the peak amplifiers 16 and 17, the 90° hybrid circuit 11, the coupler 20, a peak bias control circuit 22B, a drive level detection circuit 23B, the bias circuits 14, 15, 18, and 19, the radio frequency input terminal 101, and the radio frequency output terminal 102. With the above-described configuration, the radio frequency module 3 constitutes a Doherty amplifier circuit. The radio frequency module 3 according to the present modification example is different from the radio frequency module 1 according to the embodiment only in that the signal of the bias circuit 15 is input to the drive level detection circuit 23B instead of the radio frequency signal RF4. Hereinafter, the radio frequency module 3 according to the present modification example will be described, and the same configuration as the configuration of the radio frequency module 1 according to the embodiment will not be described, and a different configuration will be mainly described.

The bias circuit 18 supplies the bias voltage (and the bias current) to the peak amplifier 16 based on the control signal S2 output from the peak bias control circuit 22B. The bias circuit 19 supplies the bias voltage (and the bias current) to the peak amplifier 17 based on the control signal S2 output from the peak bias control circuit 22B.

The drive level detection circuit 23B is connected to the bias circuit 15 and configured to output the signal S1 indicating the drive level of the carrier amplifier 13 to the peak bias control circuit 22B.

The peak bias control circuit 22B is included in the control circuit. A first input end of the peak bias control circuit 22B is connected to the input end of the carrier amplifier 12. A second input end of the peak bias control circuit 22B is connected to the bias circuit 15 through the drive level detection circuit 23B. An output end of the peak bias control circuit 22B is connected to the bias circuits 18 and 19. That is, the peak bias control circuit 22B is configured to output the control signal S2 for varying the threshold values of the bias voltages of the peak amplifiers 16 and 17 to the bias circuits 18 and 19, based on the radio frequency signal RF2 input to the carrier amplifier 12 and the signal S1 indicating the drive level of the carrier amplifier 13.

The peak bias control circuit 22B may be connected to the input end of the 90° hybrid circuit 11 instead of the input end of the carrier amplifier 12. In this case, the peak bias control circuit 22B is configured to output the control signal S2 for varying the threshold values of the bias voltages of the peak amplifiers 16 and 17 to the bias circuits 18 and 19, based on the radio frequency signal RF1 and the signal S1.

The control signal S2 may be supplied only to the bias circuit 18 among the bias circuits 18 and 19.

In the present modification example, each of the carrier amplifier and the peak amplifier in the final stage (power stage) may be a differential amplifier, as in Modification Example 1. That is, the radio frequency module 3 may include the carrier amplifiers 12, 13a, and 13b, the peak amplifiers 16, 17a, and 17b, the coupler 20A, the bias circuits 14, 15a, 15b, 18, 19a, and 19b, and the transformers 51 and 52. In this case, the drive level detection circuit 23B may be connected to each of the bias circuits 15a and 15b.

### 4.3 Modification Example 3

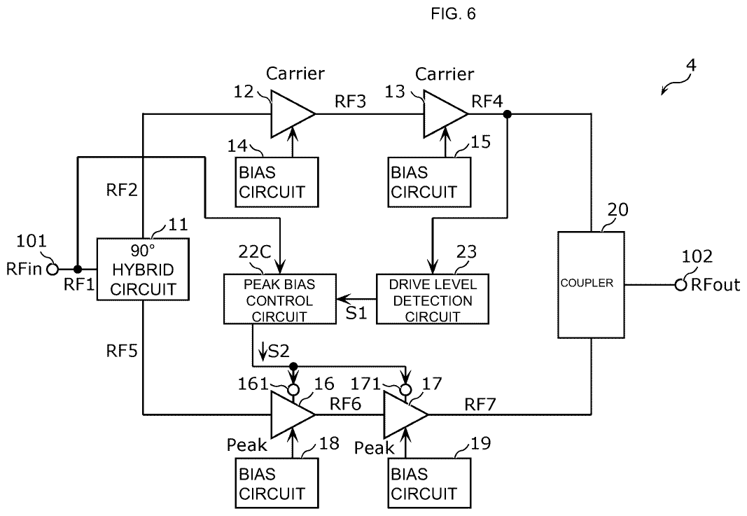

FIG. 6 is a circuit configuration diagram of a radio frequency module 4 according to Modification Example 3 of the embodiment. The radio frequency module 4 according to the present modification example includes the carrier amplifiers 12 and 13, the peak amplifiers 16 and 17, the 90° hybrid circuit 11, the coupler 20, a peak bias control circuit 22C, the drive level detection circuit 23, the bias circuits 14, 15, 18, and 19, enable terminals 161 and 171, the radio frequency input terminal 101, and the radio frequency output terminal 102. With the above-described configuration, the radio frequency module 4 constitutes a Doherty amplifier circuit. The radio frequency module 4 according to the present modification example is different from the radio frequency module 1 according to the embodiment in that the radio frequency input signal RFin is input to the peak bias control circuit 22C instead of the radio frequency signal RF2, and the control signal S2 from the peak bias control circuit 22C is output to the enable terminals 161 and 171 instead of the bias circuits 18 and 19. Hereinafter, the radio frequency module 4 according to the present modification example will be described, and the same configuration as the configuration of the radio frequency module 1 according to the embodiment will not be described, and a different configuration will be mainly described.

The enable terminal 161 is connected to the peak amplifier 16 and the peak bias control circuit 22C. The enable terminal 171 is connected to the peak amplifier 17 and the peak bias control circuit 22C.

The bias circuit 18 supplies the bias voltage (and the bias current) to the peak amplifier 16. The bias circuit 19 supplies the bias voltage (and the bias current) to the peak amplifier 17.

The peak bias control circuit 22C is included in the control circuit. A first input end of the peak bias control circuit 22C is connected to the input end of the 90° hybrid circuit 11. A second input end of the peak bias control circuit 22C is connected to the output end of the carrier amplifier 13 through the drive level detection circuit 23. That is, the peak bias control circuit 22C is configured to output the control signal S2 for varying the threshold values of the bias voltages of the peak amplifiers 16 and 17 to the enable terminals 161 and 171, based on the radio frequency input signal RFin input to the 90° hybrid circuit 11 and the signal S1 indicating the drive level of the carrier amplifier 13. With the above-described configuration, for example, the peak bias control circuit 22C controls whether or not to supply the bias voltage to the peak amplifier 16 by outputting the control signal S2 to the enable terminal 161, and controls whether or not to supply the bias voltage to the peak amplifier 17 by outputting the control signal S2 to the enable terminal 171. The radio frequency signal RF2 may be input to the peak bias control circuit 22C, as in the other modification examples. That is, the first input end of the peak bias control circuit 22C may be connected to the input end of the carrier amplifier 12.

Further, in the present modification example, each of the carrier amplifier and the peak amplifier in the final stage (power stage) may be a differential amplifier, as in Modification Example 1. That is, the radio frequency module 4 may include the carrier amplifiers 12, 13a, and 13b, the peak amplifiers 16, 17a, and 17b, the coupler 20A, the bias circuits 14, 15a, 15b, 18, 19a, and 19b, and the transformers 51 and 52. In this case, each of the peak amplifiers 16, 17a, and 17b includes an enable terminal, and the peak bias control circuit 22C outputs the control signal S2 to each enable terminal. Alternatively, the peak bias control circuit 22C may output the control signal S2 only to the enable terminal 161 of the peak amplifier 16.

Further, in the present modification example, as in Modification Example 2, the drive level detection circuit 23B connected to the bias circuit 15 (or 15a and 15b) may be provided instead of the drive level detection circuit 23.

### 5 Example

Subsequently, a plurality of specific examples of the radio frequency modules 1 to 4 will be described.

### 5.1 Example 1

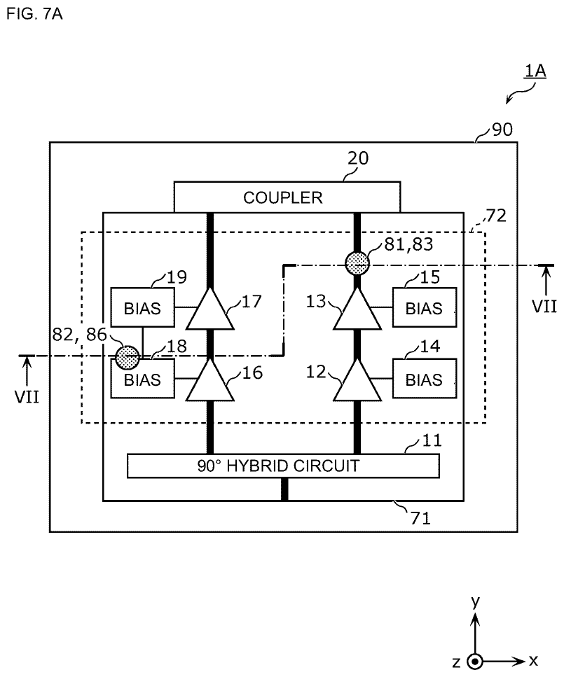

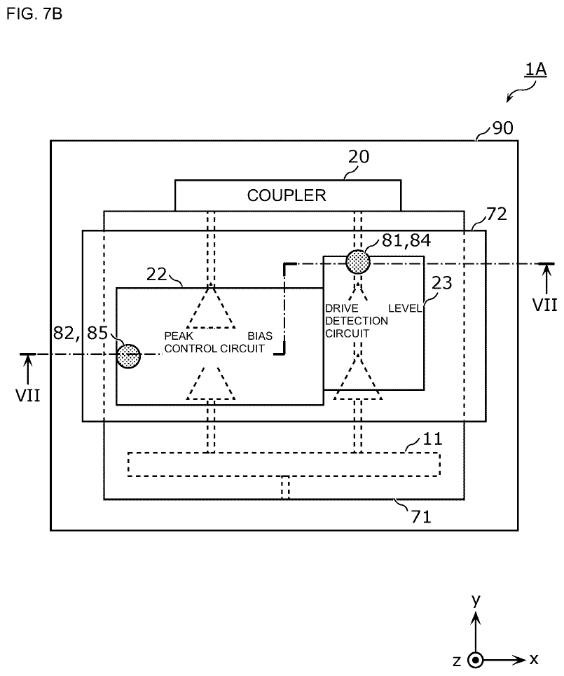

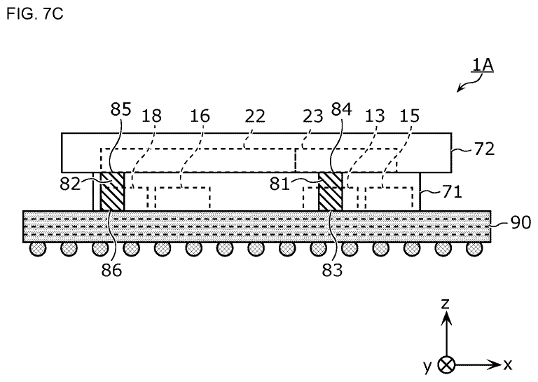

Each of FIG. 7A and FIG. 7B is a plan view of a radio frequency module 1A according to Example 1. Both FIG. 7A and FIG. 7B show a view of a main surface of a module substrate 90 from the positive side of the z-axis. In FIG. 7A, a configuration in which the integrated circuit 72 is removed from the configuration of the radio frequency module 1A, that is, the module substrate 90 and the integrated circuit 71 are shown. In FIG. 7A, a contour of the integrated circuit 72 is represented by a broken line.

FIG. 7C is a cross-sectional view of the radio frequency module 1A according to Example 1. Specifically, FIG. 7C is a synthesized cross-sectional view in which cross sections in two portions parallel to the x-axis in the VII-VII line shown in FIGS. 7A and 7B are synthesized. That is, in FIG. 7C, the cross section (yz cross section) of the portion parallel to the y-axis direction in the VII-VII line is not shown, and two xz cross sections are shown as one view.

In FIG. 7C, the constituent elements other than via conductors 81 and 82 are schematically shown at an approximate position assuming viewed from the negative side of the y-axis. In order to avoid complication of the drawings, hatching representing cross sections of the integrated circuits 71 and 72 will also be omitted. Further, some constituent elements included in the integrated circuits 71 and 72 are not shown. Specifically, the carrier amplifier 13 in the power stage, the peak amplifier 16 in the drive stage, the bias circuits 15 and 18 connected to each of the carrier amplifier 13 and the peak amplifier 16, the peak bias control circuit 22, and the drive level detection circuit 23 are shown by broken lines, and the other constituent elements are not shown. Such a drawing method is also applied to other cross-sectional views. The constituent elements not shown may be different in the cross-sectional view.

In FIGS. 7A to 7C, a part of wirings for connecting a plurality of circuit components disposed on the module substrate 90 is not shown. In FIGS. 7A to 7C, a resin member that covers the plurality of circuit components and a shield electrode layer that covers a surface of the resin member are not shown. The resin member and the shield electrode layer need not be provided.

The radio frequency module 1A shown in FIGS. 7A to 7C has the same circuit configuration as the circuit configuration of the radio frequency module 1 shown in FIG. 1. As shown in FIGS. 7A to 7C, the radio frequency module 1A includes the module substrate 90, the integrated circuit 71, the integrated circuit 72, and the coupler 20. Although not shown in FIGS. 7A to 7C, the module substrate 90 of the radio frequency module 1A is provided with the radio frequency input terminal 101 and the radio frequency output terminal 102. The integrated circuit 71 and the integrated circuit 72 are laminated. In the present example, as shown in FIG. 7C, the integrated circuit 71 is provided between the module substrate 90 and the integrated circuit 72.

The module substrate 90 is a substrate on which circuit elements constituting the radio frequency module 1A are mounted. As the module substrate 90, for example, a low temperature co-fired ceramics (LTCC) substrate or a high temperature co-fired ceramics (HTCC) substrate having a laminated structure of a plurality of dielectric layers, a component-embedded substrate, a substrate having a redistribution layer (RDL) (for example, an LTCC substrate having an RDL), a printed board, or the like is used, but the module substrate 90 is not limited thereto.

The module substrate 90 has two main surfaces facing away from each other. In the present example, the integrated circuits 71 and 72 are laminated and disposed on one main surface (upper surface) among the two main surfaces. In addition, a ground electrode layer or the like is formed in the module substrate 90 and on the main surface. As shown in FIGS. 7A and 7B, the module substrate 90 has a rectangular shape in a plan view, but the shape of the module substrate 90 is not limited thereto.

The coupler 20 is provided on a surface (main surface or side surface) of the module substrate 90. The coupler 20 may be embedded and provided inside the module substrate 90. The coupler 20 is disposed adjacent to the integrated circuit 71 in a plan view. Alternatively, the coupler 20 may overlap with the integrated circuit 71 in a plan view. The coupler 20 may be included in the integrated circuit 71 or 72.

The integrated circuit 71 is an example of a first integrated circuit and includes a carrier amplifier and a peak amplifier. The integrated circuit 71 includes a bias circuit for each of the carrier amplifier and the peak amplifier. Specifically, as shown in FIG. 7A, the integrated circuit 71 includes the carrier amplifiers 12 and 13, the peak amplifiers 16 and 17, and the bias circuits 14, 15, 18, and 19. The integrated circuit 71 includes the 90° hybrid circuit 11, but need not include the 90° hybrid circuit 11. For example, the 90° hybrid circuit 11 may be provided on the module substrate 90.

In the present example, the carrier amplifiers 12 and 13 and the peak amplifiers 16 and 17 are disposed between the 90° hybrid circuit 11 and the coupler 20 in a plan view.

The carrier amplifiers 12 and 13 are disposed side by side along the direction (y-axis direction) in which the 90° hybrid circuit 11 and the coupler 20 are arranged. Specifically, the carrier amplifier 12 in the drive stage and the carrier amplifier 13 in the power stage are linearly arranged in this order from the 90° hybrid circuit 11 toward the coupler 20. As a result, a wiring path of the radio frequency signal passing through the carrier amplifiers 12 and 13 can be minimized, and the loss can be reduced.

The peak amplifiers 16 and 17 are disposed side by side along the direction (y-axis direction) in which the 90° hybrid circuit 11 and the coupler 20 are arranged. Specifically, the peak amplifier 16 in the drive stage and the peak amplifier 17 in the power stage are linearly arranged in this order from the 90° hybrid circuit 11 toward the coupler 20. As a result, a wiring path of the radio frequency signal passing through the peak amplifiers 16 and 17 can be minimized, and the loss can be reduced.

The bias circuits 14, 15, 18, and 19 are disposed adjacent to the corresponding amplifiers. Specifically, the bias circuit 14 is disposed adjacent to the carrier amplifier 12 and is connected to a bias input terminal (not shown) of the carrier amplifier 12. The bias circuit 15 is disposed adjacent to the carrier amplifier 13 and is connected to a bias input terminal (not shown) of the carrier amplifier 13. The bias circuit 18 is disposed adjacent to the peak amplifier 16 and is connected to a bias input terminal (not shown) of the peak amplifier 16. The bias circuit 19 is disposed adjacent to the peak amplifier 17 and is connected to a bias input terminal (not shown) of the peak amplifier 17. The disposition of the bias circuits 14, 15, 18, and 19 in the integrated circuit 71 is not limited thereto. For example, the bias circuits 14, 15, 18, and 19 may be disposed adjacent to each other in the integrated circuit 71.

An electrode such as a bump electrode or a planar electrode is provided on a lower surface of the integrated circuit 71, and is electrically connected to the module substrate 90 through the electrode. The electrical connection between the integrated circuit 71 and the module substrate 90 is not particularly limited, and for example, a bonding wire may be used.

For example, the redistribution layer (not shown) is provided on a top surface of the integrated circuit 71. The redistribution layer includes an insulating layer and a wiring formed of a metal such as copper on a surface or inside of the insulating layer. The electrical connection between the integrated circuit 71 and the integrated circuit 72 through the wiring of the redistribution layer can be secured.

The bonding wire has one end connected to the module substrate 90, and may have the other end connected to the redistribution layer. For example, it is possible to input and output a signal or supply power to the integrated circuit 71 or 72 through the bonding wire.

The integrated circuit 72 is an example of a second integrated circuit and includes a control circuit. Specifically, the integrated circuit 72 includes the peak bias control circuit 22 and the drive level detection circuit 23. The peak bias control circuit 22 and the drive level detection circuit 23 are disposed adjacent to each other in the integrated circuit 72.

As can be seen by comparing FIG. 7B with FIG. 7A, the drive level detection circuit 23 overlaps with the carrier amplifier in a plan view. Specifically, the drive level detection circuit 23 overlaps with the carrier amplifier 13 in the power stage in a plan view. In the present example, the drive level detection circuit 23 further overlaps with the carrier amplifier 12 in the drive stage in a plan view, but need not overlap with the carrier amplifier 12.

In the present example, the integrated circuits 71 and 72 are electrically connected to each other such that a wiring distance between the output end of the carrier amplifier 13 in the power stage and the input end of the drive level detection circuit 23 is shortened.

Specifically, the integrated circuit 71 includes an output terminal 83. The integrated circuit 72 includes an input terminal 84. The output terminal 83 and the input terminal 84 are connected to each other through the via conductor 81. Accordingly, the drive level detection circuit 23 can detect the drive level of the carrier amplifier 13 based on the radio frequency signal RF4 output from the carrier amplifier 13, and can be used for feedback control of the threshold value of the bias voltage.

The output terminal 83 is an example of a first output terminal and is connected to the output end of the carrier amplifier. Specifically, the output terminal 83 is connected to the output end of the carrier amplifier 13 in the integrated circuit 71. The output terminal 83 is located on a wiring that connects the output end of the carrier amplifier 13 and the coupler 20. For example, the output terminal 83 overlaps with a wiring that connects the output end of the carrier amplifier 13 and the coupler 20 in a plan view.

The input terminal 84 is an example of a first input terminal and is connected to the input end of the drive level detection circuit 23. Specifically, the input terminal 84 is connected to the input end of the drive level detection circuit 23 in the integrated circuit 72. For example, the input terminal 84 overlaps with the drive level detection circuit 23 in a plan view. Alternatively, the input terminal 84 may be disposed adjacent to the drive level detection circuit 23 in a plan view.

In the present example, the output terminal 83 and the input terminal 84 overlap with each other in a plan view. Therefore, it is possible to connect the output terminal 83 and the input terminal 84 to each other at the shortest distance in the laminating direction (z-axis direction). Specifically, as shown in FIG. 7C, the output terminal 83 and the input terminal 84 are electrically connected to each other through the via conductor 81.

The via conductor 81 penetrates at least a part of the integrated circuit 71 in the z-axis direction. The via conductor 81 is formed of a metal material such as copper or aluminum. A shape of the via conductor 81 is a columnar shape, but may be a prismatic shape or a so-called oblong shape.

As described above, the output terminal 83 and the input terminal 84 overlap with each other in a plan view, so that a wiring distance between the output end of the carrier amplifier 13 in the power stage and the input end of the drive level detection circuit 23 can be shortened. As a result, it is possible to suppress the radio frequency loss due to the parasitic capacitance and the like, and it is possible to enable the drive level detection circuit 23 to detect the instantaneous fluctuation of the drive level.

The drive level detection circuit 23 overlaps with the input terminal 84 in a plan view. As a result, it is possible to shorten a wiring path in the integrated circuit 72, so that it is possible to further suppress the radio frequency loss due to the parasitic capacitance and the like, and it is possible to improve the detection accuracy of the instantaneous fluctuation of the drive level by the drive level detection circuit 23.

In the present example, as can be seen by comparing FIG. 7B with FIG. 7A, the peak bias control circuit 22 overlaps with the peak amplifier in a plan view. Specifically, the peak bias control circuit 22 overlaps with the peak amplifier 16 in the drive stage in a plan view. In the present example, the peak bias control circuit 22 further overlaps with the peak amplifier 17 in the power stage in a plan view, but need not overlap with the peak amplifier 17.

In the present example, the integrated circuits 71 and 72 are electrically connected to each other such that a wiring distance between the peak bias control circuit 22 and the bias circuit 18 of the peak amplifier 16 in the drive stage is shortened. Specifically, the integrated circuit 72 includes an output terminal 85. The integrated circuit 71 includes an input terminal 86. The output terminal 85 and the input terminal 86 are connected to each other through the via conductor 82.

The output terminal 85 is an example of a third output terminal and outputs the control signal S2 for varying the threshold value of the bias voltage of the peak amplifier. The output terminal 85 is connected to the output end of the peak bias control circuit 22 in the integrated circuit 72. For example, the output terminal 85 overlaps with the peak bias control circuit 22 in a plan view. Alternatively, the output terminal 85 is disposed adjacent to the peak bias control circuit 22 in a plan view.

The input terminal 86 is an example of a third input terminal and receives the control signal S2 for varying the threshold value of the bias voltage of the peak amplifier. The input terminal 86 is connected to the input end of the bias circuit 18 in the integrated circuit 71. For example, the input terminal 86 overlaps with the bias circuit 18 in a plan view. Alternatively, the input terminal 86 is disposed adjacent to the bias circuit 18 in a plan view.

In the present example, the output terminal 85 and the input terminal 86 overlap with each other in a plan view. Therefore, it is possible to connect the output terminal 85 and the input terminal 86 to each other at the shortest distance in the laminating direction (z-axis direction). Specifically, as shown in FIG. 7C, the output terminal 85 and the input terminal 86 are electrically connected to each other through the via conductor 82.

The via conductor 82 penetrates at least a part of the integrated circuit 71 in the z-axis direction. The via conductor 82 is formed of a metal material such as copper or aluminum. A shape of the via conductor 82 is a columnar shape, but may be a prismatic shape or a so-called oblong shape.

As shown in FIG. 1, the control signal S2 is output to the bias circuit 18 as well as the bias circuit 19. Therefore, the output terminal 85, the input terminal 86, and the via conductor 82 may overlap with the bias circuit 19, or may be disposed adjacent to the bias circuit 19 in a plan view. For example, the output terminal 85, the input terminal 86, and the via conductor 82 may be disposed between the bias circuit 18 and the bias circuit 19 in a plan view.

As described above, the output terminal 85 and the input terminal 86 overlap with each other in a plan view, so that a wiring distance between the output end of the peak bias control circuit 22 and the input end of the bias circuit 18 can be shortened. Accordingly, it is possible to suppress the deterioration in the control signal S2, and thus it is possible to ensure the accuracy of the peak bias control.

The peak bias control circuit 22 overlaps with the output terminal 85 in a plan view. As a result, a wiring path in the integrated circuit 72 can also be shortened, the deterioration in the control signal S2 can be further suppressed, and thus the accuracy of the peak bias control can be improved.

The integrated circuit 71 is formed of, for example, at least one of GaAs, SiGe, and GaN. The integrated circuit 71 is configured using Si or a complementary metal oxide semiconductor (CMOS), and may be specifically manufactured through a silicon on insulator (SOI) process.

The integrated circuit 72 is configured using, for example, Si or CMOS, and may be specifically manufactured through an SOI process. The integrated circuit 72 may be formed of the same material as the integrated circuit 71. The constituent materials of the integrated circuits 71 and 72 are not limited to the above example.

The integrated circuit 71 including the carrier amplifiers 12 and 13, and the peak amplifiers 16 and 17 may be formed of GaAs, SiGe, or GaN, and the integrated circuit 72 including the peak bias control circuit 22 and the drive level detection circuit 23 may be formed of Si or CMOS. Therefore, it is possible to improve the amplification performance of the Doherty amplifier circuit by the integrated circuit 71 and to provide the integrated circuit 72 at low cost and in a versatile manner. The drive level detection circuit 23 is provided in the integrated circuit 72, so that the size reduction of the integrated circuit 71 can be realized.

Although not shown in FIGS. 7A to 7C, the integrated circuit 72 includes an input terminal connected to the input end of the carrier amplifier. Specifically, the integrated circuit 71 includes a terminal connected to the input end of the carrier amplifier 12, and the terminal and the input terminal of the integrated circuit 72 overlap with each other in a plan view and are connected to each other through a via conductor. As a result, the peak bias control circuit 22 can detect the radio frequency signal RF2 input to the carrier amplifier 12, and can use the detected radio frequency signal RF2 for the feedforward control of the threshold value of the bias voltage.

### 5.2 Example 2

Hereinafter, specific examples of the radio frequency module 2 will be described. Hereinafter, the difference from Example 1 will be mainly described, and the description of the common points will be omitted or simplified.

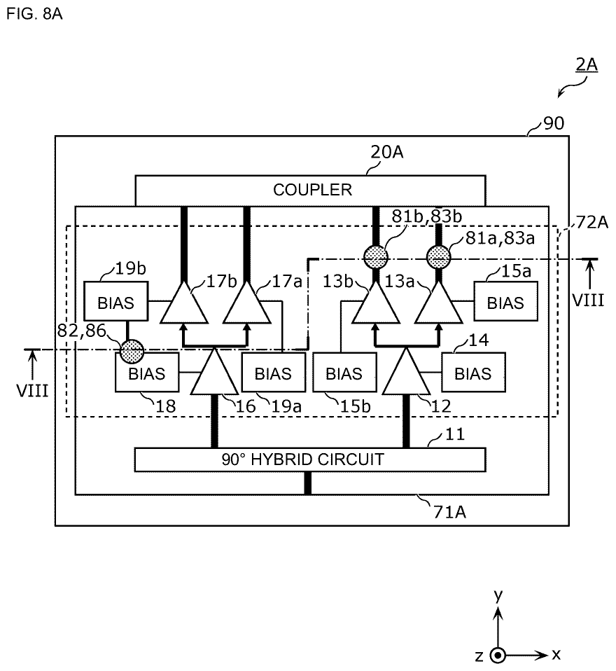

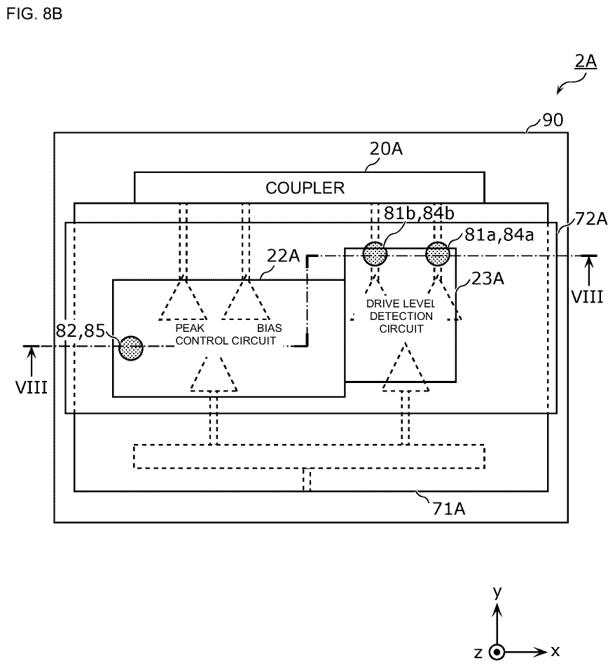

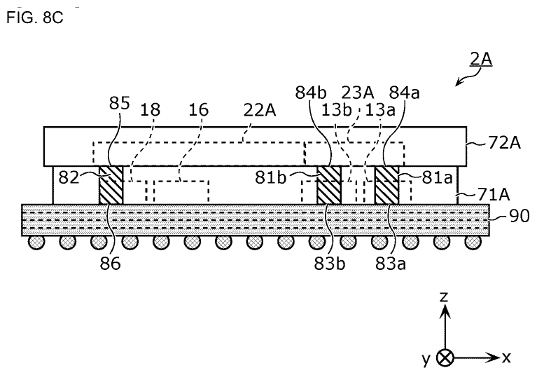

FIG. 8A and FIG. 8B are plan views of a radio frequency module 2A according to Example 2. In FIG. 8A, a configuration in which an integrated circuit 72A is removed from the configuration of the radio frequency module 2A, that is, the module substrate 90 and an integrated circuit 71A are shown. In FIG. 8A, a contour of the integrated circuit 72A is represented by a broken line.

FIG. 8C is a cross-sectional view of the radio frequency module 2A according to Example 2. Specifically, FIG. 8C is a synthesized cross-sectional view in which cross sections in two portions parallel to the x-axis in the VIII-VIII line shown in FIGS. 8A and 8B are synthesized. That is, in FIG. 8C, the cross section (yz cross section) of the portion parallel to the y-axis direction in the VIII-VIII line is not shown, and two xz cross sections are shown as one view.

The radio frequency module 2A shown in FIGS. 8A to 8C has the same circuit configuration as the circuit configuration of the radio frequency module 2 shown in FIG. 4. As shown in FIGS. 8A to 8C, the radio frequency module 2A includes the module substrate 90, the integrated circuit 71A, and the integrated circuit 72A. The integrated circuit 71A and the integrated circuit 72A are laminated. In the present example, as shown in FIG. 8C, the integrated circuit 71A is provided between the module substrate 90 and the integrated circuit 72A.

The integrated circuit 71A is an example of a first integrated circuit and includes a carrier amplifier and a peak amplifier. The integrated circuit 71A includes a bias circuit for each of the carrier amplifier and the peak amplifier. Specifically, as shown in FIG. 8A, the integrated circuit 71A includes the carrier amplifiers 12, 13a, and 13b, the peak amplifiers 16, 17a, and 17b, and the bias circuits 14, 15a, 15b, 18, 19a, and 19b. The integrated circuit 71A includes the 90° hybrid circuit 11, but need not include the 90° hybrid circuit 11. For example, the 90° hybrid circuit 11 may be provided on the module substrate 90.

In the present example, the carrier amplifiers 12, 13a, and 13b and the peak amplifiers 16, 17a, and 17b are disposed between the 90° hybrid circuit 11 and the coupler 20A in a plan view.

The carrier amplifier 12 in the drive stage and the carrier amplifiers 13a and 13b in the power stage are disposed in this order from the 90° hybrid circuit 11 toward the coupler 20A. The carrier amplifiers 13a and 13b in the power stage are disposed side by side along the x-axis direction such that the distances from the carrier amplifier 12 in the drive stage are equal to each other. As a result, a wiring path of the radio frequency signal passing through the carrier amplifier 12 and the carrier amplifier 13a or 13b can be minimized, and the loss can be reduced. The peak amplifier 16 in the drive stage and the peak amplifiers 17a and 17b in the power stage are disposed in this order from the 90° hybrid circuit 11 toward the coupler 20A. The peak amplifiers 17a and 17b in the power stage are disposed side by side along the x-axis direction such that the distances from the peak amplifier 16 in the drive stage are equal to each other. As a result, a wiring path of the radio frequency signals passing through the peak amplifier 16 and the peak amplifiers 17a and 17b can be minimized, and the loss can be reduced.

The bias circuits 14, 15a, 15b, 18, 19a, and 19b are disposed adjacent to the corresponding amplifiers. Specifically, the bias circuit 14 is disposed adjacent to the carrier amplifier 12 and is connected to a bias input terminal (not shown) of the carrier amplifier 12. The bias circuit 15a is disposed adjacent to the carrier amplifier 13a and is connected to a bias input terminal (not shown) of the carrier amplifier 13a. The bias circuit 15b is disposed adjacent to the carrier amplifier 13b and is connected to a bias input terminal (not shown) of the carrier amplifier 13b. The bias circuit 18 is disposed adjacent to the peak amplifier 16 and is connected to a bias input terminal (not shown) of the peak amplifier 16. The bias circuit 19a is disposed adjacent to the peak amplifier 17a and is connected to a bias input terminal (not shown) of the peak amplifier 17a. The bias circuit 19b is disposed adjacent to the peak amplifier 17b and is connected to a bias input terminal (not shown) of the peak amplifier 17b. The disposition of the bias circuits 14, 15a, 15b, 18, 19a, and 19b in the integrated circuit 71A is not limited thereto. For example, the bias circuits 14, 15a, 15b, 18, 19a, and 19b may be disposed adjacent to each other in the integrated circuit 71A.

An electrode such as a bump electrode or a planar electrode is provided on a lower surface of the integrated circuit 71A, and is electrically connected to the module substrate 90 through the electrode. The electrical connection between the integrated circuit 71A and the module substrate 90 is not particularly limited, and for example, a bonding wire may be used.

For example, the redistribution layer (not shown) is provided on a top surface of the integrated circuit 71A. The redistribution layer includes an insulating layer and a wiring formed of a metal such as copper on a surface or inside of the insulating layer. The electrical connection between the integrated circuit 71A and the integrated circuit 72A through the wiring of the redistribution layer can be secured.

The bonding wire has one end connected to the module substrate 90, and may have the other end connected to the redistribution layer. For example, it is possible to input and output a signal or supply power to the integrated circuit 71A or 72A through the bonding wire.

The integrated circuit 72A is an example of a second integrated circuit and includes a control circuit. Specifically, the integrated circuit 72A includes the peak bias control circuit 22A and the drive level detection circuit 23A. The peak bias control circuit 22A and the drive level detection circuit 23A are disposed adjacent to each other in the integrated circuit 72A.

As can be seen by comparing FIG. 8B with FIG. 8A, the drive level detection circuit 23A overlaps with the carrier amplifier in a plan view. Specifically, the drive level detection circuit 23A overlaps with the carrier amplifiers 13a and 13b in the power stage in a plan view. In the present example, the drive level detection circuit 23A may further overlap with the carrier amplifier 12 in the drive stage in a plan view, but need not overlap with the carrier amplifier 12.

In the present example, the integrated circuits 71A and 72A are electrically connected to each other such that a wiring distance between the output end of each of the carrier amplifiers 13a and 13b in the power stage and the input end of the drive level detection circuit 23A is shortened. Specifically, the integrated circuit 71A includes output terminals 83a and 83b. The integrated circuit 72A includes input terminals 84a and 84b. The output terminal 83a and the input terminal 84a are connected to each other through the via conductor 81a. The output terminal 83b and the input terminal 84b are connected to each other through the via conductor 81b. Accordingly, the drive level detection circuit 23A can detect the drive levels of the carrier amplifiers 13a and 13b based on the radio frequency signals RF41 and RF42 output from the carrier amplifiers 13a and 13b, and can be used for feedback control of the threshold value of the bias voltage.

The output terminal 83a is an example of a first output terminal, and is connected to the output end of the carrier amplifier. Specifically, the output terminal 83a is connected to the output end of the carrier amplifier 13a in the integrated circuit 71A. The output terminal 83a is located on a wiring that connects the output end of the carrier amplifier 13a and the coupler 20A. For example, the output terminal 83a overlaps with a wiring that connects the output end of the carrier amplifier 13a and the coupler 20A in a plan view.

The output terminal 83b is an example of a first output terminal, and is connected to the output end of the carrier amplifier. Specifically, the output terminal 83b is connected to the output end of the carrier amplifier 13b in the integrated circuit 71A. The output terminal 83b is located on a wiring that connects the output end of the carrier amplifier 13b and the coupler 20A. For example, the output terminal 83b overlaps with a wiring that connects the output end of the carrier amplifier 13b and the coupler 20A in a plan view.

The input terminal 84a is an example of a first input terminal, and is connected to the input end of the drive level detection circuit 23A. Specifically, the input terminal 84a is connected to the input end of the drive level detection circuit 23A in the integrated circuit 72A. For example, the input terminal 84a overlaps with the drive level detection circuit 23A in a plan view. Alternatively, the input terminal 84a may be disposed adjacent to the drive level detection circuit 23A in a plan view.

The input terminal 84b is an example of a first input terminal, and is connected to the input end of the drive level detection circuit 23A. Specifically, the input terminal 84b is connected to the input end of the drive level detection circuit 23A in the integrated circuit 72A. For example, the input terminal 84b overlaps with the drive level detection circuit 23A in a plan view. Alternatively, the input terminal 84b may be disposed adjacent to the drive level detection circuit 23A in a plan view.

In the present example, the output terminal 83a and the input terminal 84a overlap with each other in a plan view. Therefore, it is possible to connect the output terminal 83a and the input terminal 84a to each other at the shortest distance in the laminating direction (z-axis direction). Specifically, as shown in FIG. 8C, the output terminal 83a and the input terminal 84a are electrically connected to each other through the via conductor 81a.

The output terminal 83b and the input terminal 84b overlap with each other in a plan view. Therefore, it is possible to connect the output terminal 83b and the input terminal 84b to each other at the shortest distance in the laminating direction (z-axis direction). Specifically, as shown in FIG. 8C, the output terminal 83b and the input terminal 84b are electrically connected to each other through the via conductor 81b.

The via conductors 81a and 81b are formed of a metal material such as copper or aluminum. A shape of the via conductors 81a and 81b is a columnar shape, but may be a prismatic shape or a so-called oblong shape.

As described above, the output terminal 83a and the input terminal 84a overlap with each other in a plan view, so that a wiring distance between the output end of the carrier amplifier 13a in the power stage and the input end of the drive level detection circuit 23A can be shortened. The output terminal 83b and the input terminal 84b overlap with each other in a plan view, so that a wiring distance between the output end of the carrier amplifier 13b in the power stage and the input end of the drive level detection circuit 23A can be shortened. As a result, it is possible to suppress the radio frequency loss due to the parasitic capacitance and the like, and it is possible to enable the drive level detection circuit 23A to detect the instantaneous fluctuation of the drive level.

In the present example, a wiring distance between the output terminal 83a and the output end of the carrier amplifier 13a is equal to, for example, a wiring distance between the output terminal 83b and the output end of the carrier amplifier 13b. In the present example, since the carrier amplifiers 13a and 13b are disposed side by side in the x-axis direction, the output terminals 83a and 83b are also disposed side by side in the x-axis direction. The input terminals 84a and 84b, and the via conductors 81a and 81b are disposed side by side in the x-axis direction in the same manner. As a result, a wiring path from the output end of the carrier amplifier 13a to the drive level detection circuit 23A can be made equal to a wiring path from the output end of the carrier amplifier 13b to the drive level detection circuit 23A. By sufficiently reducing a difference between the two wiring paths, the detection accuracy of the instantaneous fluctuation of the drive level can be improved.

The drive level detection circuit 23A overlaps with the input terminals 84a and 84b in a plan view. As a result, it is possible to shorten a wiring path in the integrated circuit 72A, so that it is possible to further suppress the radio frequency loss due to the parasitic capacitance and the like, and it is possible to improve the detection accuracy of the instantaneous fluctuation of the drive level by the drive level detection circuit 23A.

In the present example, as can be seen by comparing FIG. 8B with FIG. 8A, the peak bias control circuit 22A overlaps with the peak amplifier in a plan view. Specifically, the peak bias control circuit 22A overlaps with the peak amplifier 16 in the drive stage in a plan view. In the present example, the peak bias control circuit 22A further overlaps with the peak amplifier 17a and 17b in the power stage in a plan view, but need not overlap with the peak amplifier 17a and 17b.

In the present example, the integrated circuits 71A and 72A are electrically connected to each other such that a wiring distance between the peak bias control circuit 22A and the bias circuit 18 of the peak amplifier 16 in the drive stage is shortened. Specifically, the integrated circuit 72A includes an output terminal 85. The integrated circuit 71A includes an input terminal 86. The output terminal 85 and the input terminal 86 are connected to each other through the via conductor 82. The output terminal 85, the input terminal 86, and the via conductor 82 are the same as in Example 1.

Also in the present example, as in Example 1, the output terminal 85 and the input terminal 86 overlap with each other in a plan view, so that a wiring distance between the output end of the peak bias control circuit 22A and the input end of the bias circuit 18 can be shortened. Accordingly, it is possible to suppress the deterioration in the control signal S2, and thus it is possible to ensure the accuracy of the peak bias control.

The peak bias control circuit 22A overlaps with the output terminal 85 in a plan view. As a result, a wiring path in the integrated circuit 72A can also be shortened, the deterioration in the control signal S2 can be further suppressed, and thus the accuracy of the peak bias control can be improved.

The integrated circuit 71A is formed of, for example, at least one of GaAs, SiGe, and GaN. The integrated circuit 71A is configured using Si or CMOS, and may be specifically manufactured through an SOI process.

The integrated circuit 72A is configured using, for example, Si or CMOS, and may be specifically manufactured through an SOI process. The integrated circuit 72A may be formed of the same material as the integrated circuit 71A. The constituent materials of the integrated circuits 71A and 72A are not limited to the above example.

The integrated circuit 71A including the carrier amplifiers 12, 13a, and 13b and the peak amplifiers 16, 17a, and 17b may be formed of GaAs, SiGe, or GaN, and the integrated circuit 72A including the peak bias control circuit 22A and the drive level detection circuit 23A may be formed of Si or CMOS. Therefore, it is possible to improve the amplification performance of the Doherty amplifier circuit by the integrated circuit 71A and to provide the integrated circuit 72A at low cost and in a versatile manner. The drive level detection circuit 23A is provided in the integrated circuit 72A, so that the size reduction of the integrated circuit 71A is realized.

Although not shown, the integrated circuit 72A includes an input terminal connected to the input end of the carrier amplifier, as in Example 1. Specifically, the integrated circuit 71A includes a terminal connected to the input end of the carrier amplifier 12, and the terminal and the input terminal of the integrated circuit 72A overlap with each other in a plan view and are connected to each other through a via conductor. As a result, the peak bias control circuit 22A can detect the radio frequency signal RF2 input to the carrier amplifier 12, and can use the detected radio frequency signal RF2 for the feedforward control of the threshold value of the bias voltage.

### 5.3 Example 3

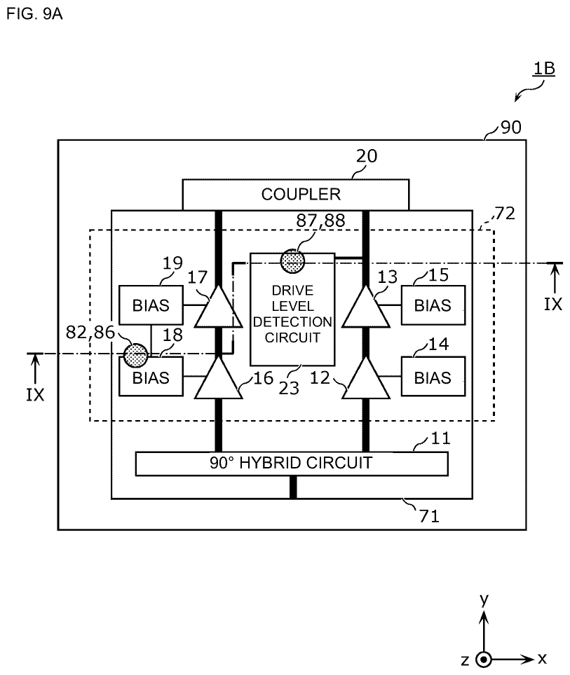

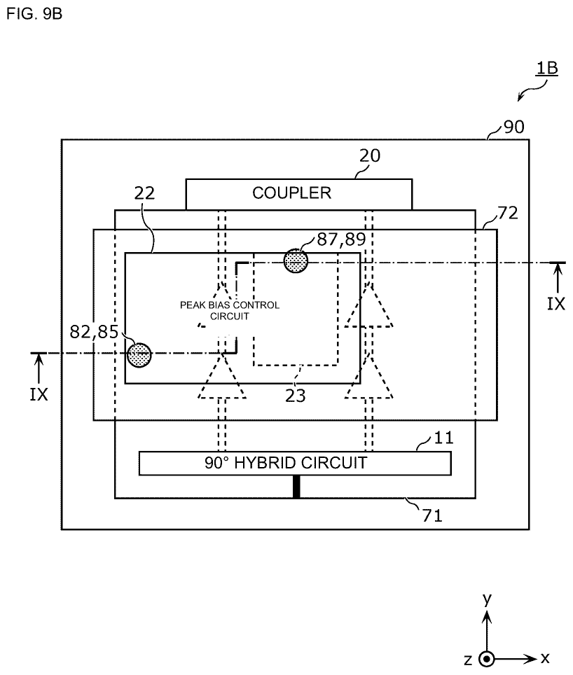

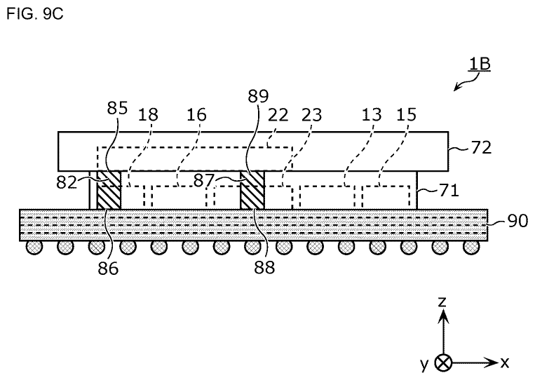

Each of FIG. 9A and FIG. 9B is a plan view of a radio frequency module 1B according to Example 3. In FIG. 9A, a configuration in which the integrated circuit 72 is removed from the configuration of the radio frequency module 1B, that is, the module substrate 90 and the integrated circuit 71 are shown. In FIG. 9A, a contour of the integrated circuit 72 is represented by a broken line.

FIG. 9C is a cross-sectional view of the radio frequency module 1B according to Example 3. Specifically, FIG. 9C is a synthesized cross-sectional view in which cross sections in two portions parallel to the x-axis in the IX-IX line shown in FIGS. 9A and 9B are synthesized. That is, in FIG. 9C, the cross section (yz cross section) of the portion parallel to the y-axis direction in the IX-IX line is not shown, and two xz cross sections are shown as one view.

The radio frequency module 1B shown in FIGS. 9A to 9C has the same circuit configuration as the circuit configuration of the radio frequency module 1 shown in FIG. 1. As shown in FIGS. 9A to 9C, the radio frequency module 1B is different from the radio frequency module 1A shown in FIGS. 7A to 7C in that the drive level detection circuit 23 is included in the integrated circuit 71.

The drive level detection circuit 23 is disposed adjacent to the carrier amplifier in the integrated circuit 71. Specifically, the drive level detection circuit 23 is disposed adjacent to the carrier amplifier 13 in the power stage. In the present example, the drive level detection circuit 23 is disposed between the carrier amplifier 13 and the peak amplifier 17. As shown in FIG. 9B, the drive level detection circuit 23 overlaps with the peak bias control circuit 22 in a plan view.

In the present example, since the drive level detection circuit 23 is included in the integrated circuit 71, a wiring distance between the output end of the carrier amplifier 13 in the power stage and the input end of the drive level detection circuit 23 can be shortened. As a result, it is possible to suppress the radio frequency loss due to the parasitic capacitance and the like, and it is possible to enable the drive level detection circuit 23 to detect the instantaneous fluctuation of the drive level.

In the present example, the integrated circuits 71 and 72 are electrically connected to each other such that a wiring distance between the output end of the drive level detection circuit 23 and the input end of the peak bias control circuit 22 is shortened. Specifically, the integrated circuit 71 includes an output terminal 88. The integrated circuit 72 includes an input terminal 89. The output terminal 88 and the input terminal 89 are connected to each other through the via conductor 87.

The output terminal 88 is an example of a second output terminal, and is a terminal for outputting the signal S1 indicating the drive level of the carrier amplifier. Specifically, the output terminal 88 is connected to the output end of the drive level detection circuit 23 in the integrated circuit 71. The output terminal 88 overlaps with the drive level detection circuit 23, for example, in a plan view. Alternatively, the output terminal 88 may be disposed adjacent to the drive level detection circuit 23 in a plan view.

The input terminal 89 is an example of a second input terminal, and is a terminal for receiving the signal S1 indicating the drive level of the carrier amplifier. Specifically, the input terminal 89 is connected to the input end of the peak bias control circuit 22 in the integrated circuit 72. For example, the input terminal 89 overlaps with the drive level detection circuit 23 and the peak bias control circuit 22 in a plan view. Alternatively, the input terminal 89 may be disposed adjacent to at least one of the drive level detection circuit 23 and the peak bias control circuit 22 in a plan view.

In the present example, the output terminal 88 and the input terminal 89 overlap with each other in a plan view. Therefore, it is possible to connect the output terminal 88 and the input terminal 89 to each other at the shortest distance in the laminating direction (z-axis direction). Specifically, as shown in FIG. 9C, the output terminal 88 and the input terminal 89 are electrically connected to each other through the via conductor 87.

The via conductor 87 penetrates at least a part of the integrated circuit 71 in the z-axis direction. The via conductor 87 is formed of a metal material such as copper or aluminum. A shape of the via conductor 87 is a columnar shape, but may be a prismatic shape or a so-called oblong shape.

As described above, the output terminal 88 and the input terminal 89 overlap with each other in a plan view, so that a wiring distance between the output end of the drive level detection circuit 23 and the input end of the peak bias control circuit 22 can be shortened. As a result, it is possible to suppress the radio frequency loss due to the parasitic capacitance and the like, and it is possible to enable the drive level detection circuit 23 to detect the instantaneous fluctuation of the drive level.

The drive level detection circuit 23 overlaps with the output terminal 88 in a plan view. As a result, it is possible to shorten a wiring path in the integrated circuit 71, so that it is possible to further suppress the loss due to the parasitic capacitance and the like, and it is possible to improve the detection accuracy of the instantaneous fluctuation of the drive level by the drive level detection circuit 23.

The peak bias control circuit 22 overlaps with the input terminal 89 in a plan view. As a result, it is possible to shorten a wiring path in the integrated circuit 72, so that it is possible to further suppress the loss due to the parasitic capacitance and the like, and it is possible to improve the detection accuracy of the instantaneous fluctuation of the drive level by the drive level detection circuit 23.

Also in the present example, as in Example 1, the output terminal 85 and the input terminal 86 overlap with each other in a plan view, so that a wiring distance between the output end of the peak bias control circuit 22 and the input end of the bias circuit 18 can be shortened. Accordingly, it is possible to suppress the deterioration in the control signal S2, and thus it is possible to ensure the accuracy of the peak bias control.

The disposition position of the drive level detection circuit 23 is not limited to the example shown in FIG. 9A. For example, the drive level detection circuit 23 may be disposed adjacent to the bias circuit 15. In addition, for example, the drive level detection circuit 23 need not overlap with the peak bias control circuit 22 in a plan view.

### 5.4 Example 4

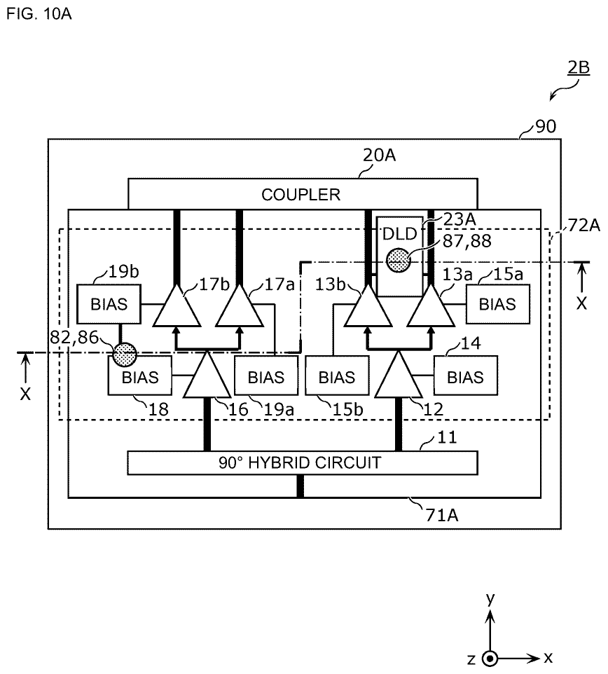

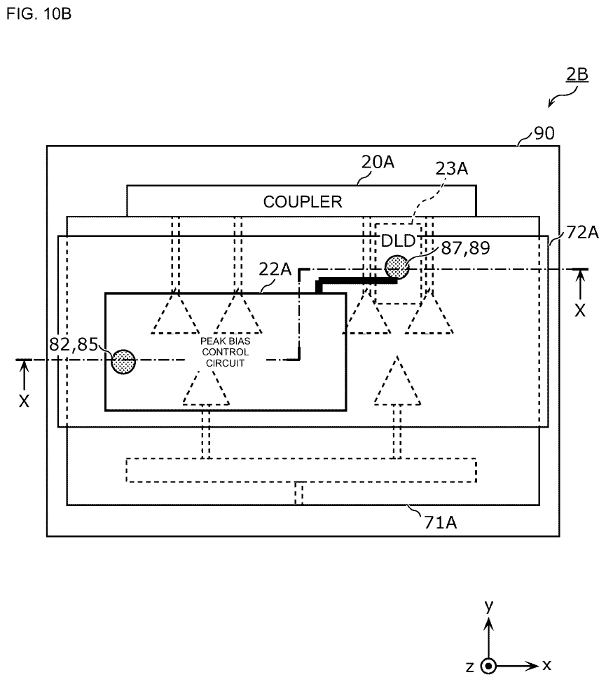

Each of FIG. 10A and FIG. 10B is a plan view of a radio frequency module 2B according to Example 4. In FIG. 10A, a configuration in which an integrated circuit 72A is removed from the configuration of the radio frequency module 2B, that is, the module substrate 90 and an integrated circuit 71A are shown. In FIG. 10A, a contour of the integrated circuit 72A is represented by a broken line.

FIG. 10C is a cross-sectional view of the radio frequency module 2B according to Example 4. Specifically, FIG. 10C is a synthesized cross-sectional view in which cross sections in two portions parallel to the x-axis in the X-X line shown in FIGS. 10A and 10B are synthesized. That is, in FIG. 10C, the cross section (yz cross section) of the portion parallel to the y-axis direction in the X-X line is not shown, and two xz cross sections are shown as one view.

The radio frequency module 2B shown in FIGS. 10A to 10C has the same circuit configuration as the circuit configuration of the radio frequency module 2 shown in FIG. 4. As shown in FIGS. 10A to 10C, the radio frequency module 2B is different from the radio frequency module 2A shown in FIGS. 8A to 8C in that the drive level detection circuit 23A is included in the integrated circuit 71A.

The drive level detection circuit 23A is disposed adjacent to the carrier amplifier in the integrated circuit 71A. Specifically, the drive level detection circuit 23A is disposed adjacent to at least one of the carrier amplifiers 13a and 13b in the power stage. In the present example, the drive level detection circuit 23A is disposed between the carrier amplifier 13a and the carrier amplifier 13b.

In the present example, since the drive level detection circuit 23A is included in the integrated circuit 71A, a wiring distance between the output end of each of the carrier amplifiers 13a and 13b in the power stage and the input end of the drive level detection circuit 23A can be shortened. As a result, it is possible to suppress the radio frequency loss due to the parasitic capacitance and the like, and it is possible to enable the drive level detection circuit 23A to detect the instantaneous fluctuation of the drive level.

In addition, since the drive level detection circuit 23A is disposed between the carrier amplifiers 13a and 13b, a wiring path from the output end of the carrier amplifier 13a to the drive level detection circuit 23A can be easily made equal to a wiring path from the output end of the carrier amplifier 13b to the drive level detection circuit 23A. By sufficiently reducing a difference between the two wiring paths, the detection accuracy of the instantaneous fluctuation of the drive level can be improved.

In the present example, the integrated circuits 71A and 72A are electrically connected to each other such that a wiring distance between the output end of the drive level detection circuit 23A and the input end of the peak bias control circuit 22A is shortened. Specifically, the integrated circuit 71A includes the output terminal 88. The integrated circuit 72A includes the input terminal 89. The output terminal 88 and the input terminal 89 are connected to each other through the via conductor 87.

As shown in FIG. 10B, in a plan view, the drive level detection circuit 23A and the peak bias control circuit 22A do not overlap with each other. Specifically, the via conductor 87, the output terminal 88, and the input terminal 89 overlap with the drive level detection circuit 23A in a plan view, but do not overlap with the peak bias control circuit 22A. Therefore, in the integrated circuit 72A, a wiring that connects the input terminal 89 and the peak bias control circuit 22A is provided.

The input terminal 89 may be provided at a position overlapping with the peak bias control circuit 22A. In this case, a wiring that connects the upper end of the via conductor 87 and the input terminal 89 is provided. The wiring is formed in, for example, a wiring layer provided on the top surface of the integrated circuit 71A. Also in the present example, the peak bias control circuit 22A may overlap with the via conductor 87 in a plan view.

The drive level detection circuit 23A overlaps with the output terminal 88 in a plan view. As a result, it is possible to shorten a wiring path in the integrated circuit 71A, so that it is possible to further suppress the radio frequency loss due to the parasitic capacitance and the like, and it is possible to improve the detection accuracy of the instantaneous fluctuation of the drive level by the drive level detection circuit 23A.

The peak bias control circuit 22A overlaps with the input terminal 89 in a plan view. As a result, it is possible to shorten a wiring path in the integrated circuit 72A, so that it is possible to further suppress the loss due to the parasitic capacitance and the like, and it is possible to improve the detection accuracy of the instantaneous fluctuation of the drive level by the drive level detection circuit 23A.

Also in the present example, as in Example 2, the output terminal 85 and the input terminal 86 overlap with each other in a plan view, so that a wiring distance between the output end of the peak bias control circuit 22A and the input end of the bias circuit 18 can be shortened.

Accordingly, it is possible to suppress the deterioration in the control signal S2, and thus it is possible to ensure the accuracy of the peak bias control.

The disposition position of the drive level detection circuit 23A is not limited to the example shown in FIG. 10A. For example, the drive level detection circuit 23A may be disposed adjacent to the bias circuits 15a and 15b.

### 5.5 Example 5

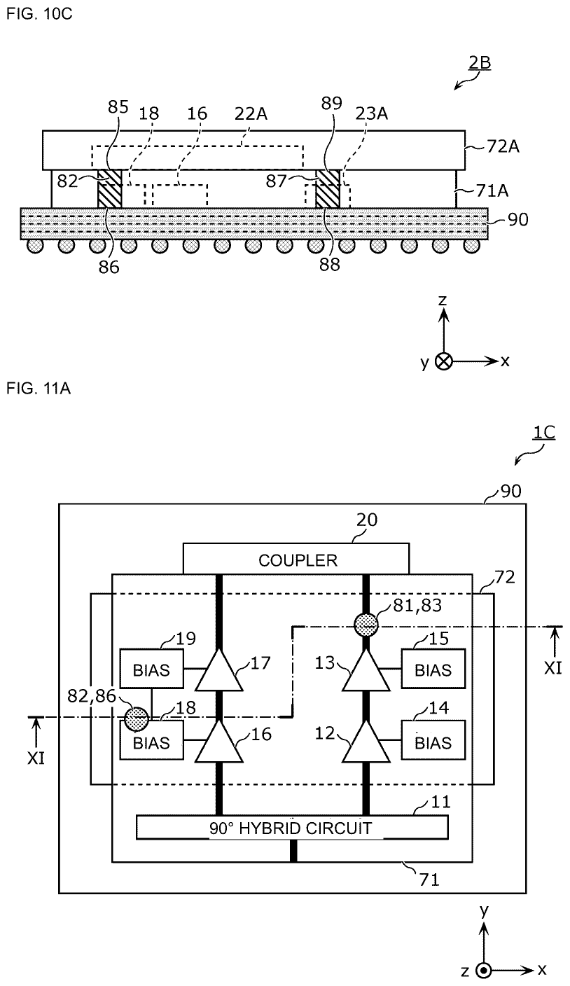

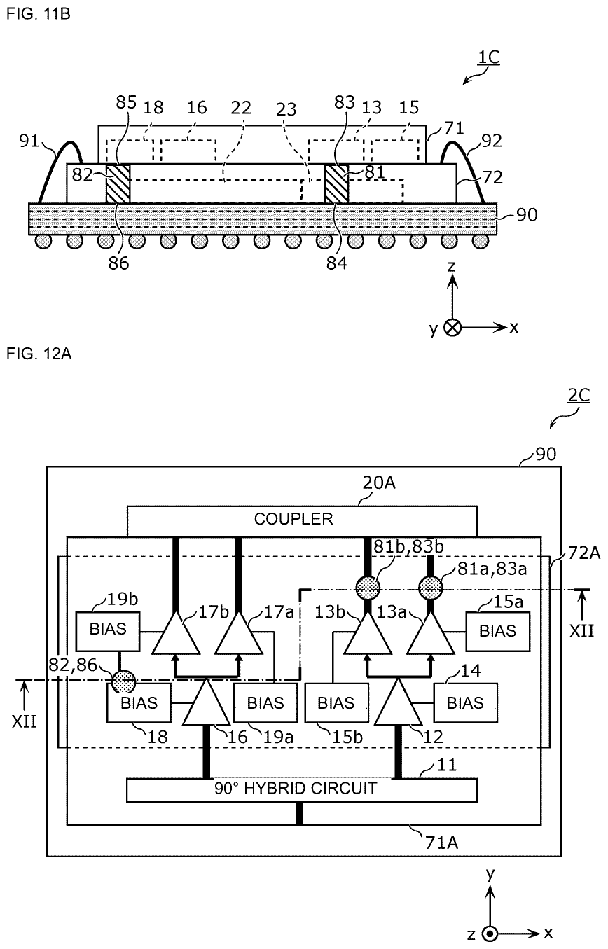

FIG. 11A is a plan view of a radio frequency module 1C according to Example 5. FIG. 11B is a cross-sectional view of the radio frequency module 1C according to Example 5. Specifically, FIG. 11B is a synthesized cross-sectional view in which cross sections in two portions parallel to the x-axis in the XI-XI line shown in FIG. 11A are synthesized. That is, in FIG. 11B, the cross section (yz cross section) of the portion parallel to the y-axis direction in the XI-XI line is not shown, and two xz cross sections are shown as one view.

The radio frequency module 1C shown in FIGS. 11A and 11B has the same circuit configuration as the circuit configuration of the radio frequency module 1 shown in FIG. 1. As shown in FIGS. 11A and 11B, the radio frequency module 1C is different from the radio frequency module 1A shown in FIGS. 7A to 7C in a positional relationship between the integrated circuit 71 and the integrated circuit 72. Specifically, in the present example, the integrated circuit 72 is provided between the module substrate 90 and the integrated circuit 71.

The integrated circuit 71 and the module substrate 90 are electrically connected to each other, for example, through the redistribution layer (not shown) provided on the top surface of the integrated circuit 72 and bonding wires 91 and 92. The redistribution layer includes an insulating layer and a wiring formed of a metal such as copper on a surface or inside of the insulating layer. The wiring of the redistribution layer may be used for the electrical connection between the integrated circuit 72 and the module substrate 90.

For example, the bonding wires 91 and 92 are used to connect the coupler 20 provided on the module substrate 90 to the output end of the carrier amplifier 13, to connect the coupler 20 to the output end of the peak amplifier 17, to connect the 90° hybrid circuit 11 to the radio frequency input terminal 101, or the like. The bonding wires 91 and 92 are metal wires formed of metal materials such as gold, silver, copper, and aluminum.

In FIG. 11A, the disposition of the drive level detection circuit 23 and the peak bias control circuit 22 is not shown, but the disposition of each constituent element included in the radio frequency module 1C according to the present example in a plan view is the same as the disposition in the radio frequency module 1A according to Example 1 shown in FIGS. 7A and 7B. That is, the drive level detection circuit 23 overlaps with the via conductor 81, the output terminal 83, and the input terminal 84 in a plan view. The peak bias control circuit 22 overlaps with the via conductor 82, the output terminal 85, and the input terminal 86 in a plan view. The modification applicable to the radio frequency module 1A is also applicable to the radio frequency module 1C.

The radio frequency module 1C according to the present example is different from the radio frequency module 1A in that the via conductors 81 and 82 are provided in the integrated circuit 72. Also in the present example, as in Example 1, the output terminal 83 and the input terminal 84 overlap with each other in a plan view, so that a wiring distance between the output end of the carrier amplifier 13 in the power stage and the input end of the drive level detection circuit 23 can be shortened. As a result, it is possible to suppress the radio frequency loss due to the parasitic capacitance and the like, and it is possible to enable the drive level detection circuit 23 to detect the instantaneous fluctuation of the drive level.

The output terminal 85 and the input terminal 86 overlap with each other in a plan view, so that a wiring distance between the output end of the peak bias control circuit 22 and the input end of the bias circuit 18 can be shortened. Accordingly, it is possible to suppress the deterioration in the control signal S2, and thus it is possible to ensure the accuracy of the peak bias control.

### 5.6 Example 6

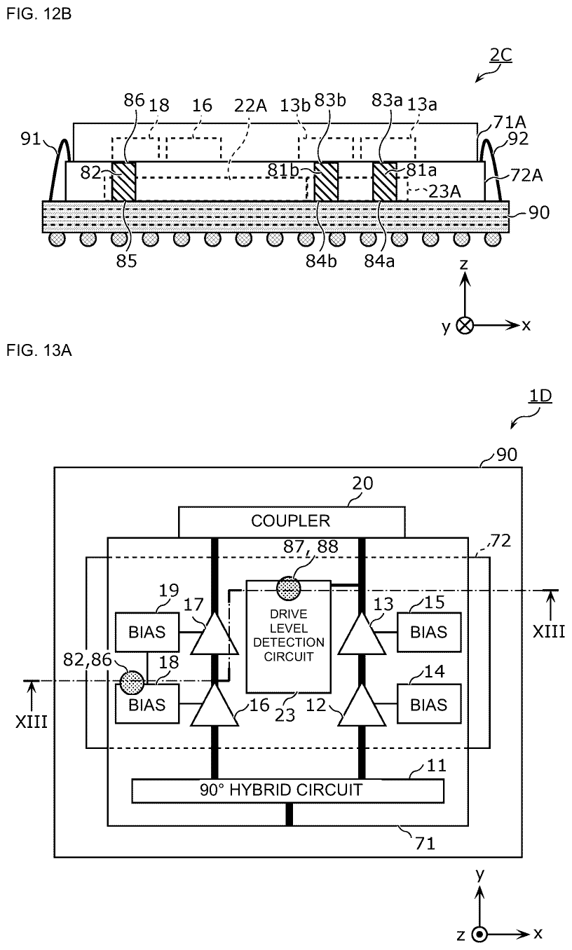

FIG. 12A is a plan view of a radio frequency module 2C according to Example 6. FIG. 12B is a cross-sectional view of the radio frequency module 2C according to Example 6. Specifically, FIG. 12B is a synthesized cross-sectional view in which cross sections in two portions parallel to the x-axis in the XII-XII line shown in FIG. 12A are synthesized. That is, in FIG. 12B, the cross section (yz cross section) of the portion of the XII-XII line parallel to the y-axis direction is not shown, and two xz cross sections are shown as one diagram.

The radio frequency module 2C shown in FIGS. 12A and 12B has the same circuit configuration as the circuit configuration of the radio frequency module 2 shown in FIG. 4. As shown in FIGS. 12A and 12B, the radio frequency module 2C is different from the radio frequency module 2A shown in FIGS. 8A to 8C in a positional relationship between the integrated circuit 71A and the integrated circuit 72A. Specifically, in the present example, the integrated circuit 72A is provided between the module substrate 90 and the integrated circuit 71A.

The integrated circuit 71A and the module substrate 90 are electrically connected to each other, for example, through the redistribution layer (not shown) provided on the top surface of the integrated circuit 72A and bonding wires 91 and 92. The redistribution layer includes an insulating layer and a wiring formed of a metal such as copper on a surface or inside of the insulating layer. The wiring of the redistribution layer may be used for the electrical connection between the integrated circuit 72A and the module substrate 90.

For example, the bonding wires 91 and 92 are used to connect the coupler 20A provided on the module substrate 90 to the output end of the carrier amplifier 13a, to connect the coupler 20A to the output end of the carrier amplifier 13b, to connect the coupler 20A to the output end of the peak amplifier 17a, to connect the coupler 20A to the output end of the peak amplifier 17b, to connect the 90° hybrid circuit 11 to the radio frequency input terminal 101, or the like. The bonding wires 91 and 92 are metal wires formed of metal materials such as gold, silver, copper, and aluminum.

In FIG. 12A, the disposition of the drive level detection circuit 23A and the peak bias control circuit 22A is not shown, but the disposition of each constituent element included in the radio frequency module 2C according to the present example in a plan view is the same as the disposition in the radio frequency module 2A according to Example 2 shown in FIGS. 8A and 8B. That is, the drive level detection circuit 23A overlaps with the via conductors 81a and 81b, the output terminals 83a and 83b, and the input terminals 84a and 84b in a plan view. The peak bias control circuit 22A overlaps with the via conductor 82, the output terminal 85, and the input terminal 86 in a plan view. The modification applicable to the radio frequency module 2A is also applicable to the radio frequency module 2C.

The radio frequency module 2C according to the present example is different from the radio frequency module 2A in that the via conductors 81a, 81b, and 82 are provided in the integrated circuit 72A. Also in the present example, as in Example 2, the output terminal 83a and the input terminal 84a overlap with each other in a plan view, and the output terminal 83b and the input terminal 84b overlap with each other in a plan view, so that a wiring distance between the output end of each of the carrier amplifiers 13a and 13b in the power stage and the input end of the drive level detection circuit 23A can be shortened. As a result, it is possible to suppress the radio frequency loss due to the parasitic capacitance and the like, and it is possible to enable the drive level detection circuit 23A to detect the instantaneous fluctuation of the drive level.

The output terminal 85 and the input terminal 86 overlap with each other in a plan view, so that a wiring distance between the output end of the peak bias control circuit 22A and the input end of the bias circuit 18 can be shortened. Accordingly, it is possible to suppress the deterioration in the control signal S2, and thus it is possible to ensure the accuracy of the peak bias control.

### 5.7 Example 7

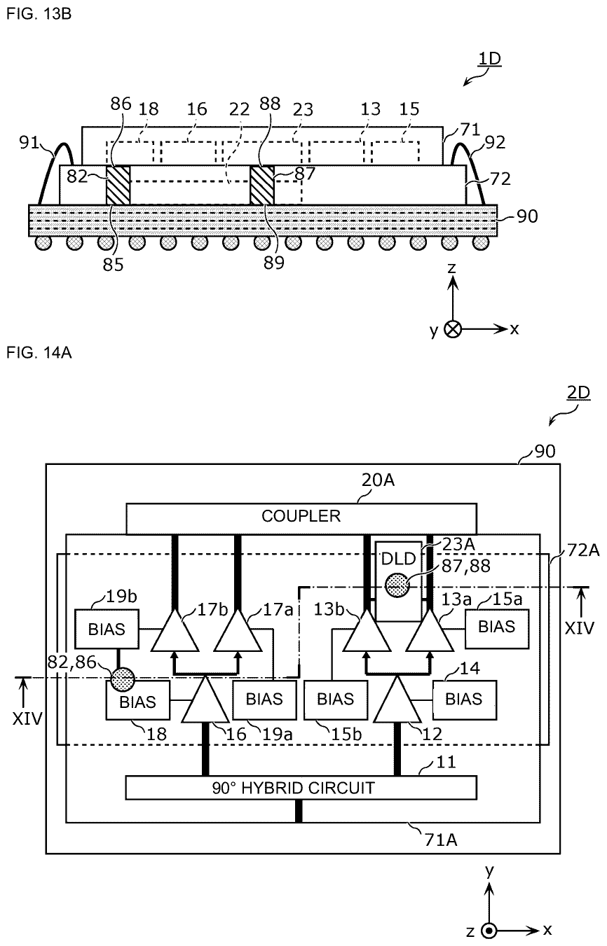

FIG. 13A is a plan view of a radio frequency module 1D according to Example 7. FIG. 13B is a cross-sectional view of the radio frequency module 1D according to Example 7. Specifically, FIG. 13B is a synthesized cross-sectional view in which cross sections in two portions parallel to the x-axis in the line XIII-XIII shown in FIG. 13A are synthesized. That is, in FIG. 13B, the cross section (yz cross section) of the portion parallel to the y-axis direction in the XIII-XIII line is not shown, and two xz cross sections are shown as one view.

The radio frequency module 1D shown in FIGS. 13A and 13B has the same circuit configuration as the circuit configuration of the radio frequency module 1 shown in FIG. 1. As shown in FIGS. 13A and 13B, the radio frequency module 1D is different from the radio frequency module 1B shown in FIGS. 9A to 9C in a positional relationship between the integrated circuit 71 and the integrated circuit 72. Specifically, in the present example, the integrated circuit 72 is provided between the module substrate 90 and the integrated circuit 71. In addition, as in Example 5, the redistribution layer (not shown) is provided on the top surface of the integrated circuit 72, and the bonding wires 91 and 92 are connected. The bonding wires 91 and 92 are the same as in Example 5, and thus the description thereof will be omitted.

In FIG. 13A, the disposition of the drive level detection circuit 23 and the peak bias control circuit 22 is not shown, but the disposition of each constituent element included in the radio frequency module 1D according to the present example in a plan view is the same as the disposition in the radio frequency module 1B according to Example 3 shown in FIGS. 9A and 9B. That is, the drive level detection circuit 23 is included in the integrated circuit 71. As a result, a wiring distance between the output end of the carrier amplifier 13 in the power stage and the input end of the drive level detection circuit 23 can be shortened. As a result, it is possible to suppress the loss due to the parasitic capacitance and the like, and it is possible to enable the drive level detection circuit 23 to detect the instantaneous fluctuation of the drive level.

The drive level detection circuit 23 overlaps with the via conductor 87, the output terminal 88, and the input terminal 89 in a plan view. The peak bias control circuit 22 overlaps with the via conductor 82, the output terminal 85, and the input terminal 86 in a plan view. The modification applicable to the radio frequency module 1B is also applicable to the radio frequency module 1D.

The radio frequency module 1D according to the present example is different from the radio frequency module 1B in that the via conductors 87 and 82 are provided in the integrated circuit 72. Also in the present example, as in Example 3, the output terminal 88 and the input terminal 89 overlap with each other in a plan view, and thus a wiring distance between the output end of the drive level detection circuit 23 and the input end of the peak bias control circuit 22 can be shortened. As a result, it is possible to suppress the radio frequency loss due to the parasitic capacitance and the like, and it is possible to enable the drive level detection circuit 23 to detect the instantaneous fluctuation of the drive level.

The output terminal 85 and the input terminal 86 overlap with each other in a plan view, so that a wiring distance between the output end of the peak bias control circuit 22 and the input end of the bias circuit 18 can be shortened. Accordingly, it is possible to suppress the deterioration in the control signal S2, and thus it is possible to ensure the accuracy of the peak bias control.

### 5.8 Example 8

FIG. 14A is a plan view of a radio frequency module 2D according to Example 8. FIG. 14B is a cross-sectional view of the radio frequency module 2D according to Example 8. Specifically, FIG. 14B is a synthesized cross-sectional view in which cross sections in two portions parallel to the x-axis in the XIV-XIV line shown in FIG. 14A are synthesized. That is, in FIG. 14B, the cross section (yz cross section) of the portion of the XIV-XIV line parallel to the y-axis direction is not shown, and two xz cross sections are shown as one view.

The radio frequency module 2D shown in FIGS. 14A and 14B has the same circuit configuration as the circuit configuration of the radio frequency module 2 shown in FIG. 4. As shown in FIGS. 14A and 14B, the radio frequency module 2D is different from the radio frequency module 2B shown in FIGS. 10A to 10C in a positional relationship between the integrated circuit 71A and the integrated circuit 72A. Specifically, in the present example, the integrated circuit 72A is provided between the module substrate 90 and the integrated circuit 71A. In addition, as in Example 6, the redistribution layer (not shown) is provided on the top surface of the integrated circuit 72A, and the bonding wires 91 and 92 are connected to each other. The bonding wires 91 and 92 are the same as in Example 6, and thus the description thereof will be omitted.

In FIG. 14A, the disposition of the drive level detection circuit 23A and the peak bias control circuit 22A is not shown, but the disposition of each constituent element included in the radio frequency module 2D according to the present example in a plan view is the same as the disposition in the radio frequency module 2B according to Example 4 shown in FIGS. 10A and 10B. That is, the drive level detection circuit 23A is included in the integrated circuit 71A. As a result, a wiring distance between the output end of each of the carrier amplifiers 13a and 13b in the power stage and the input end of the drive level detection circuit 23A can be shortened. As a result, it is possible to suppress the loss due to the parasitic capacitance and the like, and it is possible to enable the drive level detection circuit 23A to detect the instantaneous fluctuation of the drive level.

In addition, since the drive level detection circuit 23A is disposed between the carrier amplifiers 13a and 13b, a wiring path from the output end of the carrier amplifier 13a to the drive level detection circuit 23A can be easily made equal to a wiring path from the output end of the carrier amplifier 13b to the drive level detection circuit 23A. By sufficiently reducing a difference between the two wiring paths, the detection accuracy of the instantaneous fluctuation of the drive level can be improved.

The drive level detection circuit 23A overlaps with the via conductor 87, the output terminal 88, and the input terminal 89 in a plan view. The peak bias control circuit 22A overlaps with the via conductor 82, the output terminal 85, and the input terminal 86 in a plan view. The modification applicable to the radio frequency module 2B is also applicable to the radio frequency module 2D.

The radio frequency module 2D according to the present example is different from the radio frequency module 2B in that the via conductors 87 and 82 are provided in the integrated circuit 72A. Also in the present example, as in Example 4, the drive level detection circuit 23A overlaps with the output terminal 88 in a plan view, and thus a wiring path in the integrated circuit 71A can also be shortened. Therefore, the loss due to the parasitic capacitance or the like can be further suppressed, and the detection accuracy of the instantaneous fluctuation of the drive level can be improved by the drive level detection circuit 23A.

The output terminal 85 and the input terminal 86 overlap with each other in a plan view, so that a wiring distance between the output end of the peak bias control circuit 22A and the input end of the bias circuit 18 can be shortened. Accordingly, it is possible to suppress the deterioration in the control signal S2, and thus it is possible to ensure the accuracy of the peak bias control.

### 5.9 Example 9

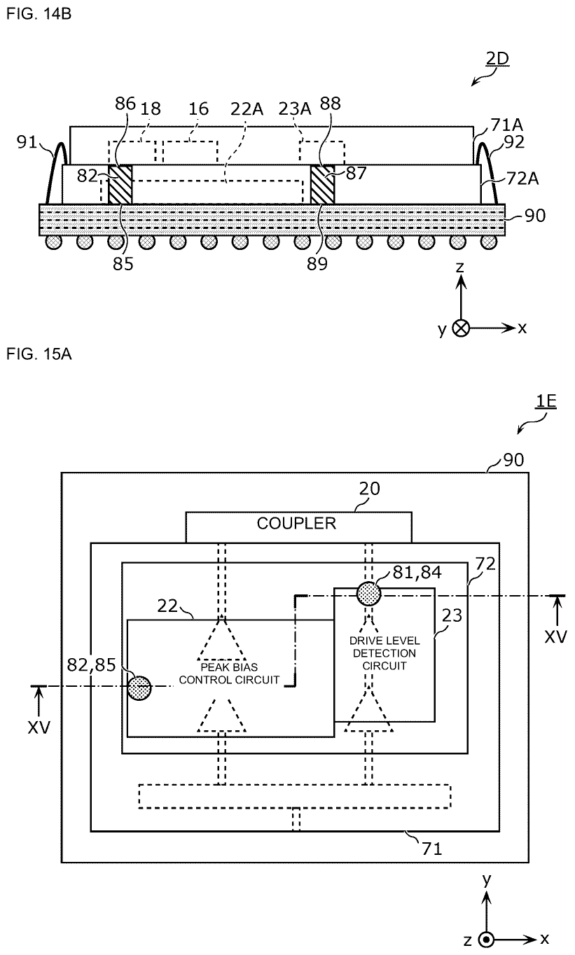

FIG. 15A is a plan view of a radio frequency module 1E according to Example 9. FIG. 15B is a cross-sectional view of the radio frequency module 1E according to Example 9. Specifically, FIG. 15B is a synthesized cross-sectional view in which cross sections in two portions parallel to the x-axis in the XV-XV line shown in FIG. 15A are synthesized. That is, in FIG. 15B, the cross section (yz cross section) of the portion parallel to the y-axis direction in the XV-XV line is not shown, and two xz cross sections are shown as one view.

The radio frequency module 1E shown in FIGS. 15A and 15B has the same circuit configuration as the circuit configuration of the radio frequency module 1 shown in FIG. 1. As shown in FIGS. 15A and 15B, the radio frequency module 1E is different from the radio frequency module 1A shown in FIGS. 7A to 7C in the sizes of the integrated circuit 71 and the integrated circuit 72. Specifically, in the present example, the integrated circuit 72 is smaller than the integrated circuit 71 in a plan view. More specifically, as shown in FIG. 15A, the entire integrated circuit 72 is disposed inside the integrated circuit 71 in a plan view.

In the present example, the integrated circuit 71 is disposed between the integrated circuit 72 and the module substrate 90. The redistribution layer (not shown) is provided on the top surface of the integrated circuit 71, and the bonding wires 91 and 92 are connected to each other. The bonding wires 91 and 92 are the same as in Example 5, and thus the description thereof will be omitted.

Since the integrated circuit 72 is smaller than the integrated circuit 71, a region in which the bonding wires 91 and 92 can be connected to the top surface of the integrated circuit 71 can be widely secured. Therefore, a degree of freedom in connection of the bonding wires 91 and 92 is increased, and thus the wiring distance can be easily shortened.

The disposition of each constituent element of the radio frequency module 1E according to the present example in a plan view is the same as the disposition in the radio frequency module 1A according to Example 1 shown in FIGS. 7A and 7B. That is, the drive level detection circuit 23 overlaps with the via conductor 81, the output terminal 83, and the input terminal 84 in a plan view. The peak bias control circuit 22 overlaps with the via conductor 82, the output terminal 85, and the input terminal 86 in a plan view. The modification applicable to the radio frequency module 1A is also applicable to the radio frequency module 1E.

Also in the present example, as in Example 1, the output terminal 83 and the input terminal 84 overlap with each other in a plan view, so that a wiring distance between the output end of the carrier amplifier 13 in the power stage and the input end of the drive level detection circuit 23 can be shortened. As a result, it is possible to suppress the radio frequency loss due to the parasitic capacitance and the like, and it is possible to enable the drive level detection circuit 23 to detect the instantaneous fluctuation of the drive level.

The output terminal 85 and the input terminal 86 overlap with each other in a plan view, so that a wiring distance between the output end of the peak bias control circuit 22 and the input end of the bias circuit 18 can be shortened. Accordingly, it is possible to suppress the deterioration in the control signal S2, and thus it is possible to ensure the accuracy of the peak bias control.

### 5.10 Example 10

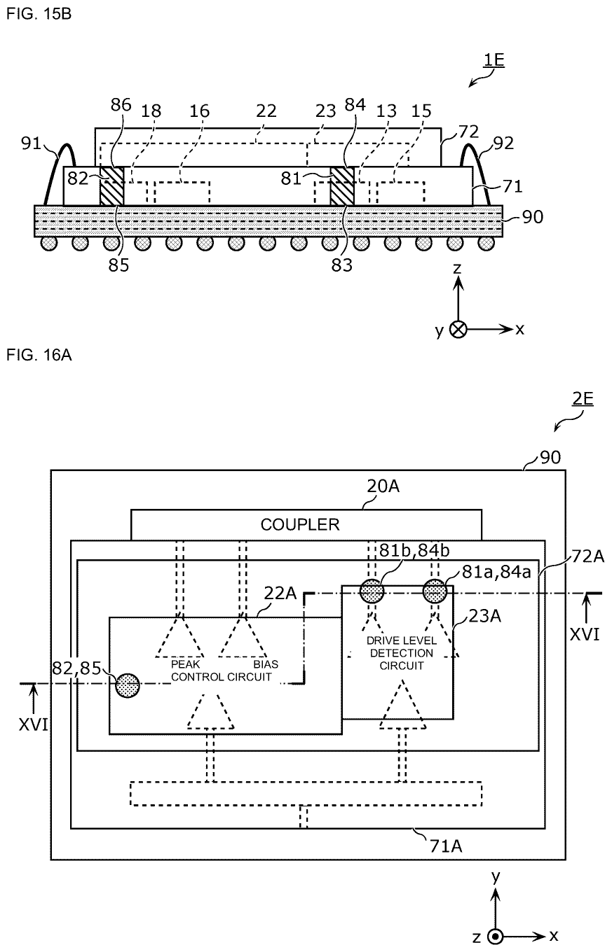

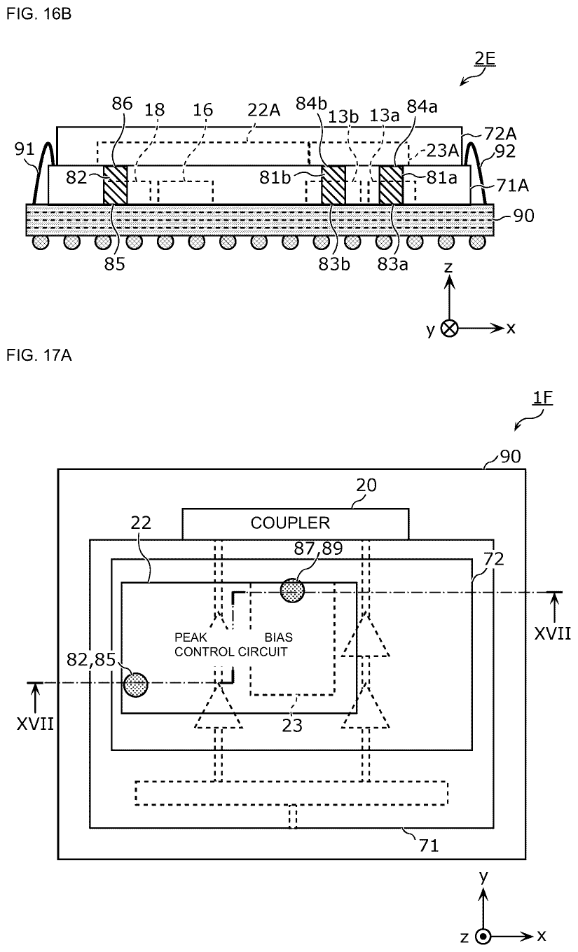

FIG. 16A is a plan view of a radio frequency module 2E according to Example 10. FIG. 16B is a cross-sectional view of the radio frequency module 2E according to Example 10. Specifically, FIG. 16B is a synthesized cross-sectional view in which cross sections in two portions parallel to the x-axis in the XVI-XVI line shown in FIG. 16A are synthesized. That is, in FIG. 16B, the cross section (yz cross section) of the portion parallel to the y-axis direction in the XVI-XVI line is not shown, and two xz cross sections are shown as one view.

The radio frequency module 2E shown in FIGS. 16A and 16B has the same circuit configuration as the circuit configuration of the radio frequency module 2 shown in FIG. 4. As shown in FIGS. 16A and 16B, the radio frequency module 2E is different from the radio frequency module 2A shown in FIGS. 8A to 8C in the sizes of the integrated circuit 71A and the integrated circuit 72A. Specifically, in the present example, the integrated circuit 72A is smaller than the integrated circuit 71A in a plan view. More specifically, as shown in FIG. 16A, the entire integrated circuit 72A is disposed inside the integrated circuit 71A in a plan view.

In the present example, the integrated circuit 71A is disposed between the integrated circuit 72A and the module substrate 90. The redistribution layer (not shown) is provided on the top surface of the integrated circuit 71A, and the bonding wires 91 and 92 are connected to the redistribution layer. The bonding wires 91 and 92 are the same as in Example 5, and thus the description thereof will be omitted.

Since the integrated circuit 72A is smaller than the integrated circuit 71A, a region in which the bonding wires 91 and 92 can be connected can be widely secured on the top surface of the integrated circuit 71A. Therefore, a degree of freedom in connection of the bonding wires 91 and 92 is increased, and thus the wiring distance can be easily shortened.

The disposition of each constituent element of the radio frequency module 2E according to the present example in a plan view is the same as the disposition in the radio frequency module 2A according to Example 2 shown in FIGS. 8A and 8B. That is, the drive level detection circuit 23A overlaps with the via conductors 81a and 81b, the output terminals 83a and 83b, and the input terminals 84a and 84b in a plan view in a plan view. The peak bias control circuit 22A overlaps with the via conductor 82, the output terminal 85, and the input terminal 86 in a plan view. The modification applicable to the radio frequency module 2A is also applicable to the radio frequency module 2E.

Also in the present example, as in Example 2, the output terminal 83a and the input terminal 84a overlap with each other in a plan view, and the output terminal 83b and the input terminal 84b overlap with each other in a plan view, so that a wiring distance between the output end of each of the carrier amplifiers 13a and 13b in the power stage and the input end of the drive level detection circuit 23A can be shortened. As a result, it is possible to suppress the radio frequency loss due to the parasitic capacitance and the like, and it is possible to enable the drive level detection circuit 23A to detect the instantaneous fluctuation of the drive level.

The output terminal 85 and the input terminal 86 overlap with each other in a plan view, so that a wiring distance between the output end of the peak bias control circuit 22A and the input end of the bias circuit 18 can be shortened. Accordingly, it is possible to suppress the deterioration in the control signal S2, and thus it is possible to ensure the accuracy of the peak bias control.

### 5.11 Example 11

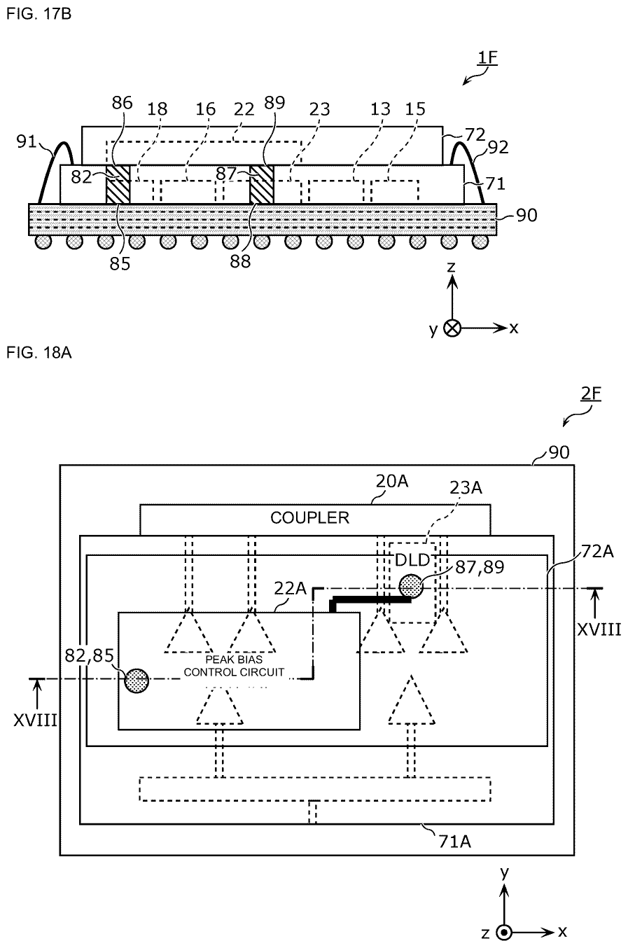

FIG. 17A is a plan view of a radio frequency module 1F according to Example 11. FIG. 17B is a cross-sectional view of the radio frequency module 1F according to Example 11. Specifically, FIG. 17B is a synthesized cross-sectional view in which cross sections in two portions parallel to the x-axis in the XVII-XVII line shown in FIG. 17A are synthesized. That is, in FIG. 17B, the cross section (yz cross section) of the portion parallel to the y-axis direction in the XVII-XVII line is not shown, and two xz cross sections are shown as one view.

The radio frequency module 1F shown in FIGS. 17A and 17B has the same circuit configuration as the circuit configuration of the radio frequency module 1 shown in FIG. 1. As shown in FIGS. 17A and 17B, the radio frequency module 1F is different from the radio frequency module 1A shown in FIGS. 7A to 7C in the sizes of the integrated circuit 71 and the integrated circuit 72. Specifically, in the present example, the integrated circuit 72 is smaller than the integrated circuit 71 in a plan view. More specifically, as shown in FIG. 17A, the entire integrated circuit 72 is disposed inside the integrated circuit 71 in a plan view.

In the present example, the integrated circuit 71 is disposed between the integrated circuit 72 and the module substrate 90. The redistribution layer (not shown) is provided on the top surface of the integrated circuit 71, and the bonding wires 91 and 92 are connected to each other. The bonding wires 91 and 92 are the same as in Example 5, and thus the description thereof will be omitted.

Since the integrated circuit 72 is smaller than the integrated circuit 71, a region in which the bonding wires 91 and 92 can be connected to the top surface of the integrated circuit 71 can be widely secured. Therefore, a degree of freedom in connection of the bonding wires 91 and 92 is increased, and thus the wiring distance can be easily shortened.

The disposition of each constituent element of the radio frequency module 1F according to the present example in a plan view is the same as the disposition in the radio frequency module 1B according to Example 3 shown in FIGS. 9A and 9B. That is, the drive level detection circuit 23 is included in the integrated circuit 71. As a result, a wiring distance between the output end of the carrier amplifier 13 in the power stage and the input end of the drive level detection circuit 23 can be shortened. As a result, it is possible to suppress the radio frequency loss due to the parasitic capacitance and the like, and it is possible to enable the drive level detection circuit 23 to detect the instantaneous fluctuation of the drive level.

The drive level detection circuit 23 overlaps with the via conductor 87, the output terminal 88, and the input terminal 89 in a plan view. The peak bias control circuit 22 overlaps with the via conductor 82, the output terminal 85, and the input terminal 86 in a plan view. The modification applicable to the radio frequency module 1B is also applicable to the radio frequency module 1F.

Also in the present example, as in Example 3, the output terminal 88 and the input terminal 89 overlap with each other in a plan view, and thus a wiring distance between the output end of the drive level detection circuit 23 and the input end of the peak bias control circuit 22 can be shortened. As a result, it is possible to suppress the loss due to the parasitic capacitance and the like, and it is possible to enable the drive level detection circuit 23 to detect the instantaneous fluctuation of the drive level.

The output terminal 85 and the input terminal 86 overlap with each other in a plan view, so that a wiring distance between the output end of the peak bias control circuit 22 and the input end of the bias circuit 18 can be shortened. Accordingly, it is possible to suppress the deterioration in the control signal S2, and thus it is possible to ensure the accuracy of the peak bias control.

### 5.12 Example 12

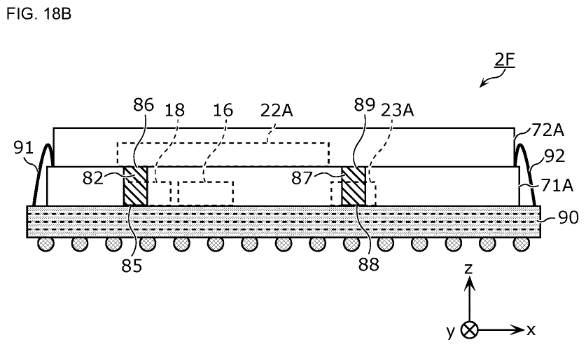

FIG. 18A is a plan view of a radio frequency module 2F according to Example 12. FIG. 18B is a cross-sectional view of the radio frequency module 2F according to Example 12. Specifically, FIG. 18B is a synthesized cross-sectional view in which cross sections in two portions parallel to the x-axis in the XVIII-XVIII line shown in FIG. 18A are synthesized. That is, in FIG. 18B, the cross section (yz cross section) of the portion parallel to the y-axis direction in the XVIII-XVIII line is not shown, and two xz cross sections are shown as one view.

The radio frequency module 2F shown in FIGS. 18A and 18B has the same circuit configuration as the circuit configuration of the radio frequency module 2 shown in FIG. 4. As shown in FIGS. 18A and 18B, the radio frequency module 2F is different from the radio frequency module 2A shown in FIGS. 8A to 8C in the sizes of the integrated circuit 71A and the integrated circuit 72A. Specifically, in the present example, the integrated circuit 72A is smaller than the integrated circuit 71A in a plan view. More specifically, as shown in FIG. 18A, the entire integrated circuit 72A is disposed inside the integrated circuit 71A in a plan view.

In the present example, the integrated circuit 71A is disposed between the integrated circuit 72A and the module substrate 90. The redistribution layer (not shown) is provided on the top surface of the integrated circuit 71A, and the bonding wires 91 and 92 are connected to the redistribution layer. The bonding wires 91 and 92 are the same as in Example 5, and thus the description thereof will be omitted.

Since the integrated circuit 72A is smaller than the integrated circuit 71A, a region in which the bonding wires 91 and 92 can be connected can be widely secured on the top surface of the integrated circuit 71A. Therefore, a degree of freedom in connection of the bonding wires 91 and 92 is increased, and thus the wiring distance can be easily shortened.

The disposition of each constituent element of the radio frequency module 2F according to the present example in a plan view is the same as the disposition in the radio frequency module 2A according to Example 2 shown in FIGS. 8A and 8B. That is, the drive level detection circuit 23A is included in the integrated circuit 71A. As a result, a wiring distance between the output end of each of the carrier amplifiers 13a and 13b in the power stage and the input end of the drive level detection circuit 23A can be shortened. As a result, it is possible to suppress the radio frequency loss due to the parasitic capacitance and the like, and it is possible to enable the drive level detection circuit 23A to detect the instantaneous fluctuation of the drive level.

In addition, since the drive level detection circuit 23A is disposed between the carrier amplifiers 13a and 13b, a wiring path from the output end of the carrier amplifier 13a to the drive level detection circuit 23A can be easily made equal to a wiring path from the output end of the carrier amplifier 13b to the drive level detection circuit 23A. By sufficiently reducing a difference between the two wiring paths, the detection accuracy of the instantaneous fluctuation of the drive level can be improved.

The drive level detection circuit 23A overlaps with the via conductor 87 and the output terminal 88 in a plan view. The peak bias control circuit 22A overlaps with the via conductor 82, the output terminal 85, and the input terminal 86 in a plan view. The modification applicable to the radio frequency module 2B is also applicable to the radio frequency module 2F.

Also in the present example, as in Example 4, the drive level detection circuit 23A overlaps with the output terminal 88 in a plan view, and thus a wiring path in the integrated circuit 71A can also be shortened. Therefore, the loss due to the parasitic capacitance or the like can be further suppressed, and the detection accuracy of the instantaneous fluctuation of the drive level can be improved by the drive level detection circuit 23A.

The output terminal 85 and the input terminal 86 overlap with each other in a plan view, so that a wiring distance between the output end of the peak bias control circuit 22A and the input end of the bias circuit 18 can be shortened. Accordingly, it is possible to suppress the deterioration in the control signal S2, and thus it is possible to ensure the accuracy of the peak bias control.

### 5.13 Other Examples

Examples 1 to 12 described above are specific implementation examples, and are not limited to the above-described examples. The circuit configuration of the radio frequency module 3 or 4 according to Modification Example 3 or 4 can also be applied.

For example, in a case where the peak bias control circuit 22 or 22A detects the radio frequency signal RF1 (radio frequency input signal RFin) as in the peak bias control circuit 22C as shown in Modification Example 3, the integrated circuit 72 or 72A includes an input terminal connected to the input end of the 90° hybrid circuit 11. Specifically, the integrated circuit 71 or 71A includes a terminal connected to the input end of the 90° hybrid circuit 11, and the terminal and the input terminal of the integrated circuit 72 or 72A overlap with each other in a plan view and are connected to each other through a via conductor. As a result, the radio frequency signal RF1 input to the 90° hybrid circuit 11 can be input to the peak bias control circuit 22 or 22A.

Alternatively, the integrated circuit 72 or 72A may be connected to the radio frequency input terminal 101 provided on the module substrate 90 or the wiring connected to the radio frequency input terminal 101 through the bonding wire. For example, one end of the bonding wire is connected to the radio frequency input terminal 101 or is connected to the wiring connected to the radio frequency input terminal 101, and the other end of the bonding wire is connected to the wiring of the redistribution layer provided on the top surface of the integrated circuit 71 or 71A. The integrated circuit 72 or 72A includes an input terminal connected to the wiring in the redistribution layer. Accordingly, the peak bias control circuit 22 or 22A in the integrated circuit 72 or 72A can detect the radio frequency signal RF1 without providing the via in the integrated circuit 71 or 71A.

The peak bias control circuit 22B and the drive level detection circuit 23B shown in Modification Example 2 may be included in the integrated circuit 72 or 72A instead of the peak bias control circuit 22 or 22A and the drive level detection circuit 23 or 23A. In this case, since the drive level detection circuit 23B is connected to the bias circuit 15 (or 15a and 15b), the drive level detection circuit 23B may overlap with the bias circuit 15 (or 15a and 15b) in a plan view, but need not overlap with the carrier amplifier 13. For example, each of the via conductor 81, the output terminal 83, and the input terminal 84 is disposed to overlap with the bias circuit 15 (or 15a and 15b) or to be adjacent to the bias circuit 15 (or 15a and 15b) in a plan view. As a result, a wiring distance of the connection between the output end of the bias circuit 15 (or 15a and 15b) and the drive level detection circuit 23B can be shortened. As a result, it is possible to suppress the radio frequency loss due to the parasitic capacitance and the like, and it is possible to enable the drive level detection circuit 23B to detect the instantaneous fluctuation of the drive level.

The peak bias control circuit 22C shown in Modification Example 3 may be included in the integrated circuit 72 or 72A instead of the peak bias control circuit 22 or 22A. In this case, since the peak bias control circuit 22C is connected to the enable terminals 161 and 171 of the peak amplifiers 16 and 17, the peak bias control circuit 22C may overlap with the enable terminal 161, for example, in a plan view, and need not overlap with the bias circuits 18 and 19 or 19a and 19b. For example, the via conductor 82, the output terminal 85, and the input terminal 86 are each disposed to overlap with the enable terminal 161 or to be adjacent to the enable terminal 161 in a plan view. Accordingly, a wiring distance between the output end of the peak bias control circuit 22C and the enable terminal 161 can be shortened. Accordingly, it is possible to suppress the deterioration in the control signal S2, and thus it is possible to ensure the accuracy of the peak bias control. For example, the via conductor 82, the output terminal 85, and the input terminal 86 may overlap with the enable terminal 171, or may be disposed adjacent to the enable terminal 171 in a plan view.

### 6. Effects and Like

As described above, the radio frequency module 1 (and 1A, 1B, 1C, 1D, 1E, 1F, 2, 2A, 2B, 2C, 2D, 2E, 2F, 3, and 4) according to the present embodiment includes the carrier amplifier and the peak amplifier, the 90° hybrid circuit 11 connected to the input end of the carrier amplifier and the input end of the peak amplifier, the coupler 20 or 20A connected to the output end of the carrier amplifier and the output end of the peak amplifier, and the control circuit configured to vary the threshold value of the bias voltage of the peak amplifier based on the radio frequency signal RF1 or RF2 input to the 90° hybrid circuit 11 or the carrier amplifier, and the signal S1 indicating the drive level of the carrier amplifier, in which the carrier amplifier and the peak amplifier are included in the integrated circuit 71 or 71A, the control circuit is included in the integrated circuit 72 or 72A, and the integrated circuit 71 or 71A and the integrated circuit 72 or 72A are laminated.

Accordingly, since the feedforward control based on the radio frequency signal RF1 or RF2 and the feedback control based on the drive level of the carrier amplifier are used, the accuracy of the peak bias control can be improved. In this case, for example, the carrier amplifier and the control circuit can be disposed side by side in the laminating direction, so that a wiring path related to the detection of the drive level of the carrier amplifier can be shortened. Therefore, the drive level of the carrier amplifier can be detected by the control circuit at a high speed and with a low loss, and thus the instantaneous fluctuation of the radio frequency signal RF4 (or RF41 and RF42) can be detected with high accuracy. In addition, since a wiring distance between the control circuit and the peak amplifier or the bias circuit thereof can be shortened, the deterioration in the control signal S2 can be suppressed, and the accuracy of the peak bias control can be ensured. Therefore, it is possible to suppress the deterioration in the quality of a radio frequency output signal RFout.

In addition, for example, the radio frequency module 1 (and 1A, 1B, 1C, 1D, 1E, 1F, 2, 2A, 2B, 2C, 2D, 2E, 2F, 3, and 4) may further include the module substrate 90, in which the integrated circuit 71 or 71A is provided between the module substrate 90 and the integrated circuit 72 or 72A.

Therefore, for example, the integrated circuit 71 or 71A including the carrier amplifier and the peak amplifier can be disposed on the main surface of the module substrate 90. For example, since a wiring path between the radio frequency input terminal 101 and the radio frequency output terminal 102 provided on the module substrate 90, and the carrier amplifier and the peak amplifier included in the integrated circuit 71 or 71A can be shortened, the loss of the radio frequency signal can be reduced, and the deterioration in the quality of the radio frequency output signal RFout can be suppressed. In addition, since the heat generated in the integrated circuit 71 or 71A can be efficiently dissipated through the module substrate 90, it is possible to contribute to the improvement of the amplification efficiency and the suppression of the deterioration in the quality of the radio frequency output signal RFout.

In addition, for example, the radio frequency module 1 (and 1A, 1B, 1C, 1D, 1E, 1F, 2, 2A, 2B, 2C, 2D, 2E, 2F, 3, and 4) may further include the module substrate 90, in which the integrated circuit 72 or 72A is provided between the module substrate 90 and the integrated circuit 71 or 71A.

Therefore, for example, the integrated circuit 72 or 72A including the control circuit can be disposed on the main surface of the module substrate 90. For example, since it is possible to shorten a wiring path for inputting the radio frequency signal RF1 to the control circuit, the radio frequency signal RF1 or RF2 can be detected at a high speed and with a low loss. In a case where the accuracy of the feedforward control is improved, the accuracy of the peak bias control is also improved, and it is possible to suppress the deterioration in the quality of the radio frequency output signal RFout. In addition, for example, the integrated circuit 71 or 71A including the carrier amplifier and the peak amplifier can be disposed in contact with the top surface of the metal shield electrode layer provided to cover the integrated circuits 71 or 71A, and 72 or 72A and the module substrate 90. Since the heat generated in the integrated circuit 71 or 71A can be efficiently dissipated through the shield electrode layer, it is possible to contribute to the improvement of the amplification efficiency and the suppression of the deterioration in the quality of the radio frequency output signal RFout.

In addition, for example, the control circuit may include the drive level detection circuit 23 or 23A connected to the output end of the carrier amplifier and configured to output the signal indicating the drive level of the carrier amplifier, and the peak bias control circuit 22, 22A, or 22B connected to the input end of the 90° hybrid circuit 11 or the input end of the carrier amplifier, and the drive level detection circuit 23 or 23A, and configured to output the control signal S2 for varying the threshold value of the bias voltage of the peak amplifier to bias circuits 18 and 19 (or 19a and 19b) of the peak amplifier.

Therefore, the carrier amplifier and the drive level detection circuit 23 or 23A can be disposed side by side in the laminating direction, and thus a wiring path for connecting the output end of the carrier amplifier and the drive level detection circuit 23 or 23A can be shortened. Therefore, the radio frequency signal RF4 (or RF41 and RF42) from the carrier amplifier can be detected at a high speed and with a low loss by the drive level detection circuit 23 or 23A, and thus the instantaneous fluctuation of the radio frequency signal RF4 (or RF41 and RF42) can be detected with high accuracy. In addition, since a wiring distance between the control circuit and the bias circuit of the peak amplifier can be shortened, the deterioration in the control signal S2 can be suppressed, and the accuracy of the peak bias control can be ensured. Therefore, it is possible to suppress the deterioration in the quality of a radio frequency output signal RFout.

In addition, for example, the carrier amplifier may include the carrier amplifier 12 having the input end connected to the 90° hybrid circuit 11, and the carrier amplifier 13 (or 13a and 13b) having the input end connected to the output end of the carrier amplifier 12, and the output end of the carrier amplifier 13 (or 13a and 13b) is connected to the coupler 20.

Therefore, the carrier amplifier is realized with a multi-stage configuration of the amplifier, and thus it is possible to perform amplification with low distortion and high efficiency.

In addition, for example, the drive level detection circuit 23 or 23A may overlap with the carrier amplifier 13 (or 13a and 13b) in a plan view of the module substrate 90.

As a result, it is possible to connect the drive level detection circuit 23 or 23A and the carrier amplifier 13 (or 13a and 13b) to each other at the shortest distance in the laminating direction (z-axis direction) of the integrated circuit. As a result, it is possible to suppress the radio frequency loss due to the parasitic capacitance and the like, and it is possible to enable the drive level detection circuit 23 or 23A to detect the instantaneous fluctuation of the drive level.

In addition, for example, the carrier amplifier may include the two carrier amplifiers 13a and 13b, and the two carrier amplifiers 13a and 13b may be connected in parallel between the carrier amplifier 12 and the coupler 20A.

As a result, the carrier amplifiers 13a and 13b constitute the differential amplifier, and thus it is possible to suppress noise and suppress the deterioration in the quality of the radio frequency output signal RFout.

In addition, for example, the drive level detection circuit 23A may overlap with each of the two carrier amplifiers 13a and 13b in a plan view of the module substrate 90.

As a result, it is possible to connect the drive level detection circuit 23A and the carrier amplifiers 13a and 13b to each other at the shortest distance in the laminating direction (z-axis direction) of the integrated circuit. As a result, it is possible to suppress the radio frequency loss due to the parasitic capacitance and the like, and it is possible to enable the drive level detection circuit 23A to detect the instantaneous fluctuation of the drive level.

In addition, for example, the integrated circuit 71 or 71A may include the output terminal 83 (or 83a and 83b) connected to the output end of the carrier amplifier, the integrated circuit 72 may include the input terminal 84 (or 84a and 84b) connected to the input end of the drive level detection circuit 23 or 23A, and the output terminal 83 (or 83a and 83b) and the input terminal 84 (or 84a and 84b) may overlap with each other in a plan view of the module substrate 90.

As a result, it is possible to connect the drive level detection circuit 23 or 23A and the carrier amplifier 13 (or 13a and 13b) to each other at the shortest distance in the laminating direction (z-axis direction) of the integrated circuit. As a result, it is possible to suppress the radio frequency loss due to the parasitic capacitance and the like, and it is possible to enable the drive level detection circuit 23 or 23A to detect the instantaneous fluctuation of the drive level.

In addition, for example, the radio frequency module 1 (and 1B, 1D, 1F, 2, 2B, 2D, 2F, 3, and 4) may further include the drive level detection circuit 23 or 23A connected to the output end of the carrier amplifier and configured to output the signal S1 indicating the drive level of the carrier amplifier, in which the control circuit includes the peak bias control circuit 22, 22A, or 22B connected to the input end of the 90° hybrid circuit 11 or the input end of the carrier amplifier, and the drive level detection circuit 23 or 23A, and configured to output the control signal S2 for varying the threshold value of the bias voltage of the peak amplifier to the bias circuits 18 and 19 (or 19a and 19b) of the peak amplifier.

Accordingly, since a wiring distance between the control circuit and the bias circuit of the peak amplifier can be shortened, the deterioration in the control signal S2 can be suppressed, and the accuracy of the peak bias control can be ensured. Therefore, it is possible to suppress the deterioration in the quality of a radio frequency output signal RFout.

In addition, for example, the drive level detection circuit 23 or 23A may be included in the integrated circuit 71 or 71A.

Accordingly, since the drive level detection circuit 23 or 23A is included in the integrated circuit 71 or 71A, a wiring distance between the output end of the carrier amplifier 13 (or 13a and 13b) in the power stage and the input end of the drive level detection circuit 23 or 23A can be shortened. As a result, it is possible to suppress the radio frequency loss due to the parasitic capacitance and the like, and it is possible to enable the drive level detection circuit 23 or 23A to detect the instantaneous fluctuation of the drive level.

In addition, for example, the carrier amplifier may include the carrier amplifier 12 having the input end connected to the 90° hybrid circuit 11, and the carrier amplifier 13 (or 13a and 13b) having the input end connected to the output end of the carrier amplifier 12, and the output end of the carrier amplifier 13 (or 13a and 13b) is connected to the coupler 20.

Therefore, the carrier amplifier is realized with a multi-stage configuration of the amplifier, and thus it is possible to perform amplification with low distortion and high efficiency.

In addition, for example, the carrier amplifier may include the two carrier amplifiers 13a and 13b, and the two carrier amplifiers 13a and 13b may be connected in parallel between the carrier amplifier 12 and the coupler 20A.

As a result, the carrier amplifiers 13a and 13b constitute the differential amplifier, and thus it is possible to suppress noise and suppress the deterioration in the quality of the radio frequency output signal RFout.

In addition, for example, the drive level detection circuit 23A may be disposed between the two carrier amplifiers 13a and 13b in a plan view of the module substrate 90.

As a result, a wiring path from the output end of the carrier amplifier 13a to the drive level detection circuit 23A can be easily made equal to a wiring path from the output end of the carrier amplifier 13b to the drive level detection circuit 23A. By sufficiently reducing a difference between the two wiring paths, the detection accuracy of the instantaneous fluctuation of the drive level can be improved.

In addition, for example, the integrated circuit 71 or 71A may include the output terminal 88 that outputs the signal S1 indicating the drive level of the carrier amplifier, the integrated circuit 72 or 72A may include the input terminal 89 that receives the signal S1 indicating the drive level of the carrier amplifier, and the output terminal 88 and the input terminal 89 may overlap with each other in a plan view of the module substrate 90.

As a result, the output terminal 88 and the input terminal 89 overlap with each other in a plan view, so that a wiring distance between the output end of the drive level detection circuit 23 and the input end of the peak bias control circuit 22 can be shortened. As a result, it is possible to suppress the radio frequency loss due to the parasitic capacitance and the like, and it is possible to enable the drive level detection circuit 23 to detect the instantaneous fluctuation of the drive level.

In addition, for example, the integrated circuit 71 or 71A may include the output terminal 85 that outputs the control signal S2 for varying the threshold value of the bias voltage of the peak amplifier, the integrated circuit 72 or 72A may include the input terminal 86 that receives the control signal S2 for varying the threshold value of the bias voltage of the peak amplifier, and the output terminal 85 and the input terminal 86 may overlap with each other in a plan view of the module substrate 90.

As a result, it is possible to shorten a wiring distance between the output end of the peak bias control circuit 22, 22A, or 22B and the input ends of the bias circuits 18 and 19 (or 19a and 19b). Accordingly, it is possible to suppress the deterioration in the control signal S2, and thus it is possible to ensure the accuracy of the peak bias control.

In addition, for example, the peak amplifier includes the peak amplifier 16 having the input end connected to the 90° hybrid circuit 11 and the peak amplifier 17 (or 17a and 17b) having the input end connected to the output end of the peak amplifier 16, and the output end of the peak amplifier 17 (or 17a and 17b) is connected to the coupler 20.

Therefore, the peak amplifier is realized with a multi-stage configuration of the amplifier, and thus it is possible to perform amplification with low distortion and high efficiency.

In addition, for example, the peak bias control circuit 22, 22A, 22B, or 22C overlaps with the peak amplifier 16 in a plan view.

As a result, a wiring distance between the output end of the peak bias control circuit 22, 22A, 22B, or 22C and the input end of the peak amplifier 16 or the bias circuit 18 can be shortened. Accordingly, it is possible to suppress the deterioration in the control signal S2, and thus it is possible to ensure the accuracy of the peak bias control.

The radio frequency module 3 according to the present embodiment includes the carrier amplifier and the peak amplifier, the 90° hybrid circuit 11 connected to the input end of the carrier amplifier and the input end of the peak amplifier, the coupler 20 connected to the output end of the carrier amplifier and the output end of the peak amplifier, and the control circuit configured to vary the threshold value of the bias voltage of the peak amplifier, in which the first input end of the control circuit is connected to the input end of the carrier amplifier, the second input end of the control circuit is connected to the bias circuit of the carrier amplifier, the output end of the control circuit is connected to the bias circuit of the peak amplifier, the carrier amplifier and the peak amplifier are included in the integrated circuit 71 or 71A, the control circuit is included in the integrated circuit 72 or 72A, and the integrated circuit 71 or 71A and the integrated circuit 72 or 72A are laminated.

Accordingly, since the feedforward control based on the radio frequency signal RF2 and the feedback control based on the drive level of the carrier amplifier are used, the accuracy of the peak bias control can be improved. In this case, for example, the bias circuit of the carrier amplifier and the control circuit can be disposed side by side in the laminating direction, so that a wiring path related to the detection of the drive level of the carrier amplifier can be shortened. Therefore, the drive level of the carrier amplifier can be detected by the control circuit at a high speed and with a low loss, and thus the instantaneous fluctuation of the radio frequency signal RF4 (or RF41 and RF42) can be detected with high accuracy. In addition, since a wiring distance between the control circuit and the peak amplifier or the bias circuit thereof can be shortened, the deterioration in the control signal S2 can be suppressed, and the accuracy of the peak bias control can be ensured. Therefore, it is possible to suppress the deterioration in the quality of a radio frequency output signal RFout.

The radio frequency module 4 according to the present embodiment includes the carrier amplifier and the peak amplifier, the 90° hybrid circuit 11 connected to the input end of the carrier amplifier and the input end of the peak amplifier, the coupler 20 connected to the output end of the carrier amplifier and the output end of the peak amplifier, and the control circuit, in which the first input end of the control circuit is connected to the input end of the 90° hybrid circuit 11 and the input end of the carrier amplifier, the second input end of the control circuit is connected to the output end of the carrier amplifier, the output end of the control circuit is connected to the peak amplifier, the carrier amplifier and the peak amplifier are included in the integrated circuit 71 or 71A, the control circuit is included in the integrated circuit 72 or 72A, and the integrated circuit 71 or 71A and the integrated circuit 72 or 72A are laminated.

Accordingly, since the feedforward control based on the radio frequency signal RF1 or RF2 and the feedback control based on the drive level of the carrier amplifier are used, the accuracy of the peak bias control can be improved. In this case, for example, the carrier amplifier and the control circuit can be disposed side by side in the laminating direction, so that a wiring path related to the detection of the drive level of the carrier amplifier can be shortened. Therefore, the drive level of the carrier amplifier can be detected by the control circuit at a high speed and with a low loss, and thus the instantaneous fluctuation of the radio frequency signal RF4 (or RF41 and RF42) can be detected with high accuracy. In addition, since a wiring distance between the control circuit and the bias circuit of the peak amplifier can be shortened, the deterioration in the control signal S2 can be suppressed, and the accuracy of the peak bias control can be ensured. Therefore, it is possible to suppress the deterioration in the quality of a radio frequency output signal RFout.

### OTHER EMBODIMENTS

Although the radio frequency module according to the embodiment of the present disclosure has been described with reference to the embodiment and the modification examples, the radio frequency module according to the embodiment of the present disclosure is not limited to the embodiment and the modification examples described above. The present disclosure also includes another embodiment realized by combining any constituent elements in the embodiment and the modification examples described above, a modification example obtained by making various modifications that can be conceived of by those skilled in the art with respect to the embodiment and the modification examples described above within a range that does not deviate from the gist of the present disclosure, or various devices with built-in radio frequency modules.

For example, in the radio frequency module according to the embodiment and the modification examples described above, another circuit element, another wiring, or the like may be inserted into the path for connecting the circuit elements and the signal paths disclosed in the drawings.

For example, a coupler may be provided at a branch portion of the path in a case where the radio frequency signals RF1, RF2, and RF4 are input to the control circuit. The present disclosure also includes an embodiment obtained by various modifications that those skilled in the art can conceive for each embodiment, and an embodiment realized by optionally combining the constituent elements and functions in each embodiment within a range not departing from the gist of the present disclosure.

Hereinafter, features of the radio frequency module described based on the above-described embodiment will be described.

<1>

A radio frequency module including: a carrier amplifier and a peak amplifier; a branching circuit connected to an input end of the carrier amplifier and an input end of the peak amplifier; a synthesis circuit connected to an output end of the carrier amplifier and an output end of the peak amplifier; and a control circuit configured to vary a threshold value of a bias voltage of the peak amplifier based on a radio frequency signal input to the branching circuit or the carrier amplifier, and a signal indicating a drive level of the carrier amplifier, in which the carrier amplifier and the peak amplifier are included in a first integrated circuit, the control circuit is included in a second integrated circuit, and the first integrated circuit and the second integrated circuit are laminated.

<2>

The radio frequency module according to <1>, further including: a module substrate, in which the first integrated circuit is provided between the module substrate and the second integrated circuit.

<3>

The radio frequency module according to <1>, further including: a module substrate, in which the second integrated circuit is provided between the module substrate and the first integrated circuit.

<4>

The radio frequency module according to <2> or <3>, in which the control circuit includes a drive level detection circuit connected to the output end of the carrier amplifier and configured to output the signal indicating the drive level of the carrier amplifier, and a peak bias control circuit connected to an input end of the branching circuit or the input end of the carrier amplifier, and the drive level detection circuit, and configured to output a control signal for varying the threshold value of the bias voltage of the peak amplifier to a bias circuit of the peak amplifier.

<5>

The radio frequency module according to <4>, in which the carrier amplifier includes a first amplifier having an input end connected to the branching circuit, and a second amplifier having an input end connected to an output end of the first amplifier, and an output end of the second amplifier is connected to the synthesis circuit.

<6>

The radio frequency module according to <5>, in which the drive level detection circuit overlaps with the second amplifier in a plan view of the module substrate.

<7>

The radio frequency module according to <5> or <6>, in which the carrier amplifier includes two second amplifiers, and the two second amplifiers are connected in parallel between the first amplifier and the synthesis circuit.

<8>

The radio frequency module according to <7>, in which the drive level detection circuit overlaps with each of the two second amplifiers in a plan view of the module substrate.

<9>

The radio frequency module according to any one of <4> to <8>, in which the first integrated circuit includes a first output terminal connected to the output end of the carrier amplifier, the second integrated circuit includes a first input terminal connected to an input end of the drive level detection circuit, and the first output terminal and the first input terminal overlap with each other in a plan view of the module substrate.

<10>

The radio frequency module according to <2> or <3>, further including: a drive level detection circuit connected to the output end of the carrier amplifier and configured to output the signal indicating the drive level of the carrier amplifier, in which the control circuit includes a peak bias control circuit connected to an input end of the branching circuit or the input end of the carrier amplifier, and the drive level detection circuit, and configured to output a control signal for varying the threshold value of the bias voltage of the peak amplifier to a bias circuit of the peak amplifier.

<11>

The radio frequency module according to <10>, in which the drive level detection circuit is included in the first integrated circuit.

<12>

The radio frequency module according to <11>, in which the carrier amplifier includes a first amplifier having an input end connected to the branching circuit, and a second amplifier having an input end connected to an output end of the first amplifier, and an output end of the second amplifier is connected to the synthesis circuit.

<13>

The radio frequency module according to <12>, in which the carrier amplifier includes two second amplifiers, and the two second amplifiers are connected in parallel between the first amplifier and the synthesis circuit.

<14>

The radio frequency module according to <13>, in which the drive level detection circuit is disposed between the two second amplifiers in a plan view of the module substrate.

<15>

The radio frequency module according to any one of <11> to <14>, in which the first integrated circuit includes a second output terminal that outputs the signal indicating the drive level of the carrier amplifier, the second integrated circuit includes a second input terminal that receives the signal indicating the drive level of the carrier amplifier, and the second output terminal and the second input terminal overlap with each other in a plan view of the module substrate.

<16>

The radio frequency module according to any one of <2> to <15>, in which the first integrated circuit includes a third output terminal that outputs a control signal for varying the threshold value of the bias voltage of the peak amplifier, the second integrated circuit includes a third input terminal that receives the control signal for varying the threshold value of the bias voltage of the peak amplifier, and the third output terminal and the third input terminal overlap with each other in a plan view of the module substrate.

<17>

The radio frequency module according to any one of <1> to <16>, in which the peak amplifier includes a third amplifier having an input end connected to the branching circuit, and a fourth amplifier having an input end connected to an output end of the third amplifier, and an output end of the fourth amplifier is connected to the synthesis circuit.

<18>

The radio frequency module according to <17>, in which the control circuit overlaps with the third amplifier in a plan view.

<19>

A radio frequency module including: a carrier amplifier and a peak amplifier; a branching circuit connected to an input end of the carrier amplifier and an input end of the peak amplifier; a synthesis circuit connected to an output end of the carrier amplifier and an output end of the peak amplifier; and a control circuit configured to vary a threshold value of a bias voltage of the peak amplifier, in which a first input end of the control circuit is connected to the input end of the carrier amplifier, a second input end of the control circuit is connected to a bias circuit of the carrier amplifier, an output end of the control circuit is connected to a bias circuit of the peak amplifier, the carrier amplifier and the peak amplifier are included in a first integrated circuit, the control circuit is included in a second integrated circuit, and the first integrated circuit and the second integrated circuit are laminated.

<20>

A radio frequency module including: a carrier amplifier and a peak amplifier; a branching circuit connected to an input end of the carrier amplifier and an input end of the peak amplifier; a synthesis circuit connected to an output end of the carrier amplifier and an output end of the peak amplifier; and a control circuit, in which a first input end of the control circuit is connected to an input end of the branching circuit or the input end of the carrier amplifier, a second input end of the control circuit is connected to the output end of the carrier amplifier, an output end of the control circuit is connected to the peak amplifier, the carrier amplifier and the peak amplifier are included in a first integrated circuit, the control circuit is included in a second integrated circuit, and the first integrated circuit and the second integrated circuit are laminated.

The present disclosure can be widely used in a communication device such as a mobile phone, as a radio frequency module disposed in a multi-band compatible front end portion.

What is claimed is:

1. A radio frequency module comprising:
a carrier amplifier and a peak amplifier;
a branching circuit connected to an input end of the carrier amplifier and an input end of the peak amplifier;
a synthesis circuit connected to an output end of the carrier amplifier and an output end of the peak amplifier; and
a control circuit configured to vary a threshold value of a bias voltage of the peak amplifier based on a radio frequency signal input to the branching circuit or the carrier amplifier, and a signal indicating a drive level of the carrier amplifier,
wherein the carrier amplifier and the peak amplifier are included in a first integrated circuit,
the control circuit is included in a second integrated circuit, and
the first integrated circuit and the second integrated circuit are laminated.

2. The radio frequency module according to claim 1, further comprising:
a module substrate,
wherein the first integrated circuit is provided between the module substrate and the second integrated circuit.

3. The radio frequency module according to claim 1, further comprising:
a module substrate,
wherein the second integrated circuit is provided between the module substrate and the first integrated circuit.

4. The radio frequency module according to claim 3,
wherein the control circuit includes
a drive level detection circuit connected to the output end of the carrier amplifier and configured to output the signal indicating the drive level of the carrier amplifier, and
a peak bias control circuit connected to an input end of the branching circuit or the input end of the carrier amplifier, and the drive level detection circuit, and configured to output a control signal for varying the threshold value of the bias voltage of the peak amplifier to a bias circuit of the peak amplifier.

5. The radio frequency module according to claim 4,
wherein the carrier amplifier includes
a first amplifier having an input end connected to the branching circuit, and
a second amplifier having an input end connected to an output end of the first amplifier, and
an output end of the second amplifier is connected to the synthesis circuit.

6. The radio frequency module according to claim 5,
wherein the drive level detection circuit overlaps with the second amplifier in a plan view of the module substrate.

7. The radio frequency module according to claim 5,
wherein the carrier amplifier includes two second amplifiers, and
the two second amplifiers are connected in parallel between the first amplifier and the synthesis circuit.

8. The radio frequency module according to claim 7,
wherein the drive level detection circuit overlaps with each of the two second amplifiers in a plan view of the module substrate.

9. The radio frequency module according to claim 4,
wherein the first integrated circuit includes a first output terminal connected to the output end of the carrier amplifier,
the second integrated circuit includes a first input terminal connected to an input end of the drive level detection circuit, and
the first output terminal and the first input terminal overlap with each other in a plan view of the module substrate.

10. The radio frequency module according to claim 3, further comprising:
a drive level detection circuit connected to the output end of the carrier amplifier and configured to output the signal indicating the drive level of the carrier amplifier,
wherein the control circuit includes
a peak bias control circuit connected to an input end of the branching circuit or the input end of the carrier amplifier, and the drive level detection circuit, and configured to output a control signal for varying the threshold value of the bias voltage of the peak amplifier to a bias circuit of the peak amplifier.

11. The radio frequency module according to claim 10,
wherein the drive level detection circuit is included in the first integrated circuit.

12. The radio frequency module according to claim 11,
wherein the carrier amplifier includes
a first amplifier having an input end connected to the branching circuit, and
a second amplifier having an input end connected to an output end of the first amplifier, and
an output end of the second amplifier is connected to the synthesis circuit.

13. The radio frequency module according to claim 12,
wherein the carrier amplifier includes two second amplifiers, and
the two second amplifiers are connected in parallel between the first amplifier and the synthesis circuit.

14. The radio frequency module according to claim 13,
wherein the drive level detection circuit is disposed between the two second amplifiers in a plan view of the module substrate.

15. The radio frequency module according to claim 11,
wherein the first integrated circuit includes a second output terminal that outputs the signal indicating the drive level of the carrier amplifier,
the second integrated circuit includes a second input terminal that receives the signal indicating the drive level of the carrier amplifier, and
the second output terminal and the second input terminal overlap with each other in a plan view of the module substrate.

16. The radio frequency module according to claim 3,
wherein the first integrated circuit includes a third output terminal that outputs a control signal for varying the threshold value of the bias voltage of the peak amplifier,
the second integrated circuit includes a third input terminal that receives the control signal for varying the threshold value of the bias voltage of the peak amplifier, and
the third output terminal and the third input terminal overlap with each other in a plan view of the module substrate.

17. The radio frequency module according to claim 3,
wherein the peak amplifier includes
a third amplifier having an input end connected to the branching circuit, and
a fourth amplifier having an input end connected to an output end of the third amplifier, and
an output end of the fourth amplifier is connected to the synthesis circuit.

18. The radio frequency module according to claim 17,
wherein the control circuit overlaps with the third amplifier in a plan view.

19. A radio frequency module comprising:
a carrier amplifier and a peak amplifier;
a branching circuit connected to an input end of the carrier amplifier and an input end of the peak amplifier;
a synthesis circuit connected to an output end of the carrier amplifier and an output end of the peak amplifier; and
a control circuit configured to vary a threshold value of a bias voltage of the peak amplifier,
wherein a first input end of the control circuit is connected to the input end of the carrier amplifier,
a second input end of the control circuit is connected to a bias circuit of the carrier amplifier,
an output end of the control circuit is connected to a bias circuit of the peak amplifier,
the carrier amplifier and the peak amplifier are included in a first integrated circuit,
the control circuit is included in a second integrated circuit, and
the first integrated circuit and the second integrated circuit are laminated.

20. A radio frequency module comprising:
a carrier amplifier and a peak amplifier;
a branching circuit connected to an input end of the carrier amplifier and an input end of the peak amplifier;
a synthesis circuit connected to an output end of the carrier amplifier and an output end of the peak amplifier; and
a control circuit,
wherein a first input end of the control circuit is connected to an input end of the branching circuit or the input end of the carrier amplifier,
a second input end of the control circuit is connected to the output end of the carrier amplifier,
an output end of the control circuit is connected to the peak amplifier,
the carrier amplifier and the peak amplifier are included in a first integrated circuit,
the control circuit is included in a second integrated circuit, and
the first integrated circuit and the second integrated circuit are laminated.
